(19) United States
(12) Patent Application Publication
(10) Pub. No.: US 2026/0231753 A1
(43) Pub. Date: Aug. 6, 2026

(54) SEMICONDUCTOR PACKAGE

(71) Applicant: SAMSUNG ELECTRONICS CO., LTD., Suwon-si (KR)

(72) Inventors: Hyun YANG, Suwon-si (KR); Sungkeun PARK, Suwon-si (KR); Chanwook PARK, Suwon-si (KR); Jaemok JUNG, Suwon-si (KR); Taeoh HA, Suwon-si (KR)

(73) Assignee: SAMSUNG ELECTRONICS CO., LTD., Suwon-si (KR)

(21) Appl. No.: 19/529,865

(22) Filed: Feb. 4, 2026

(30) Foreign Application Priority Data
Feb. 4, 2025 (KR) 10-2025-0014074

(51) Int. Cl. H10W 20/43; H10W 20/20; H10W 74/10

(52) U.S. Cl. CPC H10W 20/43; H10W 20/20; H10W 74/141

(57) ABSTRACT

A semiconductor package includes a redistribution structure, a semiconductor chip located on the redistribution structure and including a semiconductor substrate, a wiring structure, and a plurality of dummy pads, the semiconductor substrate including an active surface and an inactive surface opposite to the active surface, and the wiring structure being on the active surface of the semiconductor substrate, and a plurality of dummy wires each having a first end in contact with the dummy pad of the semiconductor chip and a second end opposite to the first end and apart from the semiconductor chip and the redistribution structure. The dummy pads of the semiconductor chip further include a lateral-side dummy pad on a lateral surface of the semiconductor substrate, and the dummy wires include a lateral-side dummy wire having a first end in contact with the lateral-side dummy pad of the semiconductor chip.

### CROSS-REFERENCE TO RELATED APPLICATION

This application is based on and claims priority to Korean Patent Application No. 10-2025-0014074, filed on Feb. 4, 2025, in the Korean Intellectual Property Office, the disclosure of which is incorporated by reference herein in its entirety.

### BACKGROUND

The present disclosure relates to a semiconductor package, and more particularly, to a semiconductor package including wires.

As the storage capacity of semiconductor chips increases, semiconductor packages including semiconductor chips are required to be thinner and lighter. In addition, research has been conducted to include semiconductor chips with various functions in semiconductor packages and to drive the semiconductor chips at high speed. Following this trend, there is an increasing need for downscaled and multifunctional semiconductor chips for use in electronic components. In addition, in the packaging field, intensive research has been conducted on methods of dissipating heat from the inside of semiconductor packages while downscaling the semiconductor packages based on small-sized semiconductor chips.

### SUMMARY

One or more example embodiments provide a semiconductor package capable of efficiently dissipate heat generated by a semiconductor chip therein to the outside.

Example embodiments are not limited by the above description, and other unmentioned aspects will be clearly understood by one of ordinary skill in the art from embodiments described herein.

According to an aspect of an example embodiment, there is provided a semiconductor package including: a redistribution structure; a semiconductor chip on the redistribution structure, the semiconductor chip including a semiconductor substrate, a wiring structure, and a plurality of dummy pads, the semiconductor substrate including an active surface and an inactive surface opposite to the active surface, and the wiring structure being on the active surface of the semiconductor substrate; and a plurality of dummy wires each having a first end in contact with a corresponding one of the plurality of dummy pads of the semiconductor chip and a second end opposite to the first end, the second end being spaced apart from the semiconductor chip and the redistribution structure. The plurality of dummy pads of the semiconductor chip include a lateral-side dummy pad on a lateral surface of the semiconductor substrate, and the plurality of dummy wires include a lateral-side dummy wire, the first end of the lateral-side dummy wire being in contact with the lateral-side dummy pad of the semiconductor chip.

According to another aspect of an example embodiment, there is provided a semiconductor package including: a lower redistribution structure; a lower semiconductor chip on the lower redistribution structure, the lower semiconductor chip including a lower semiconductor substrate, a lower wiring structure, and a plurality of lower dummy pads, the lower semiconductor substrate including an active surface and an inactive surface opposite to the active surface, and the lower wiring structure being on the active surface of the lower semiconductor substrate; a plurality of lower dummy wires each having a first end in contact with a corresponding one of the plurality of lower dummy pads of the lower semiconductor chip and a second end opposite to the first end, the second end of each of the plurality of lower dummy wires being spaced apart from the lower redistribution structure and the lower semiconductor chip; a lower molding layer on the lower redistribution structure, the lower molding layer being in contact with the lower semiconductor chip and the plurality of lower dummy wires; a plurality of lower through vias on the lower redistribution structure, the plurality of lower through vias extending from a lower surface of the lower molding layer to an upper surface of the lower molding layer; and an upper redistribution structure on the lower molding layer, the upper redistribution structure being electrically connected to the plurality of lower through via.

According to another aspect of an example embodiment, there is provided a semiconductor package including: a lower redistribution structure; a lower semiconductor chip on the lower redistribution structure, the lower semiconductor chip including a lower semiconductor substrate, a lower wiring structure, and a plurality of lower dummy pads, the lower semiconductor substrate including an active surface and an inactive surface opposite to the active surface, and the lower wiring structure being on the active surface of the lower semiconductor substrate; a plurality of lower dummy wires each having a first end in contact with a corresponding one of the plurality of lower dummy pads of the lower semiconductor chip and a second end opposite to the first end, the second end of each of the plurality of lower dummy wires being spaced apart from the lower redistribution structure and the lower semiconductor chip; a lower molding layer on the lower redistribution structure, the lower molding layer being in contact with the lower semiconductor chip and the plurality of lower dummy wires; a plurality of lower through vias located on the lower redistribution structure and extending from a lower surface of the lower molding layer to an upper surface thereof; an upper redistribution structure on the lower molding layer, the upper redistribution structure being electrically connected to the plurality of lower through vias; an upper semiconductor chip on the upper redistribution structure, the upper semiconductor chip including an upper semiconductor substrate, an upper wiring structure, and a plurality of upper dummy pads, the upper semiconductor substrate including an active surface and an inactive surface opposite to the active surface, and the upper wiring structure on the active surface of the upper semiconductor substrate; and a plurality of upper dummy wires each having a first end in contact with a corresponding one of the plurality of upper dummy pads and a second end opposite to the first end, the second end of each of the plurality of upper dummy wires being spaced apart from the upper redistribution structure and the upper semiconductor chip.

According to another aspect of an example embodiment, there is provided a method of manufacturing a semiconductor package, the method including: providing a semiconductor chip on a redistribution structure, the semiconductor chip including a plurality of devices formed on an active surface and a plurality of dummy pads insulated from the plurality of devices; forming a plurality of dummy wires in contact with the plurality of dummy pads; forming a molding layer on the redistribution structure to cover the semiconductor chip and the plurality of dummy wires.

The plurality of dummy pads may include a lateral-side dummy pad formed on a lateral surface of the semiconductor chip and a back-side lower dummy pad formed on an inactive surface of the semiconductor chip.

The method may further include providing another semiconductor chip on another redistribution structure, wherein the redistribution structure and the other redistribution structure are commonly provided on a carrier substrate; and performing a dicing operation to cut the carrier substrate and the molding layer along a cutting layer between the semiconductor chip from the other semiconductor chip.

### BRIEF DESCRIPTION OF DRAWINGS

The above and other objects, features and advantages will be more apparent from the following description of example embodiments, taken in conjunction with the accompanying drawings, in which:

FIG. 1 is a plan view of a semiconductor package according to example embodiments;

FIG. 2 is a cross-sectional view of a semiconductor package according to example embodiments;

FIG. 3 is a cross-sectional view of a semiconductor package according to example embodiments;

FIG. 4 is a cross-sectional view of a semiconductor package according to example embodiments;

FIG. 5 is a cross-sectional view of a semiconductor package according to example embodiments;

FIG. 6 is a cross-sectional view of a semiconductor package according to example embodiments;

FIG. 7 is a plan view of a semiconductor package according to example embodiments;

FIG. 8 is a cross-sectional view of a semiconductor package according to example embodiments;

FIG. 9 is a cross-sectional view of a semiconductor package according to example embodiments;

FIG. 10 is a cross-sectional view of a semiconductor package according to example embodiments;

FIG. 11 is a cross-sectional view of a semiconductor package according to example embodiments; and

FIGS. 12A, 12B, 12C, 12D, 12E, 12F, 12G, 12H, 12I and 12J are cross-sectional views illustrating a method of manufacturing a semiconductor package, according to example embodiments.

### DETAILED DESCRIPTION

Hereinafter, embodiments are described in detail with reference to the accompanying drawings. The inventive concept is described more fully hereinafter with reference to the accompanying drawings, in which embodiments are shown. Embodiments described herein are example embodiments, and thus, the present disclosure is not limited thereto, and may be realized in various other forms. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. Each embodiment provided in the following description is not excluded from being associated with one or more features of another example or another embodiment also provided herein or not provided herein but consistent with the present disclosure. Like components are denoted by like reference numerals throughout the specification, and repeated descriptions thereof are omitted.

Spatially relative terms, such as “upper,” “above,” “lower,” “below,” “up,” “down,” “front,” “back,” “left,” “right,” and the like, may be used herein for ease of description to describe one element or feature’s relationship to another element(s) or feature(s) as illustrated in the figures. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

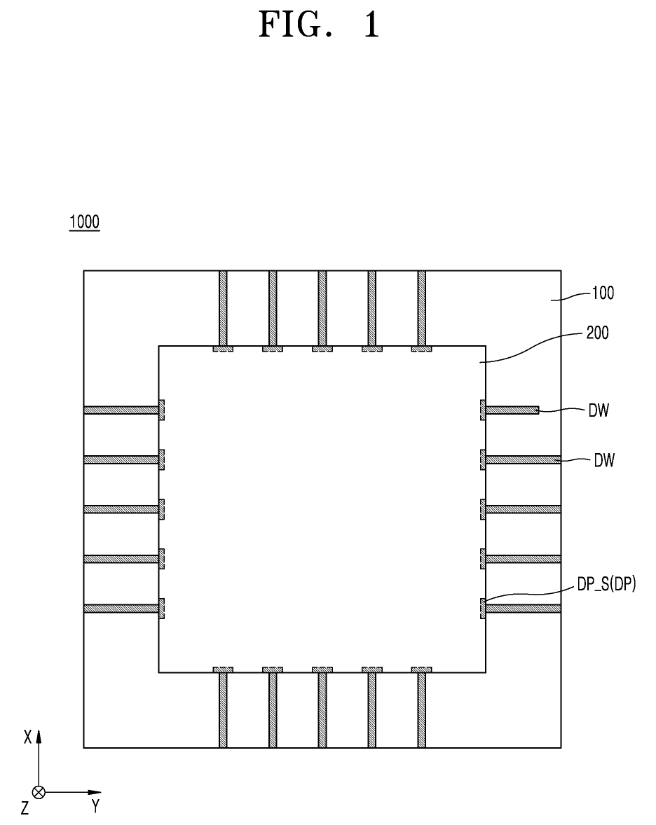

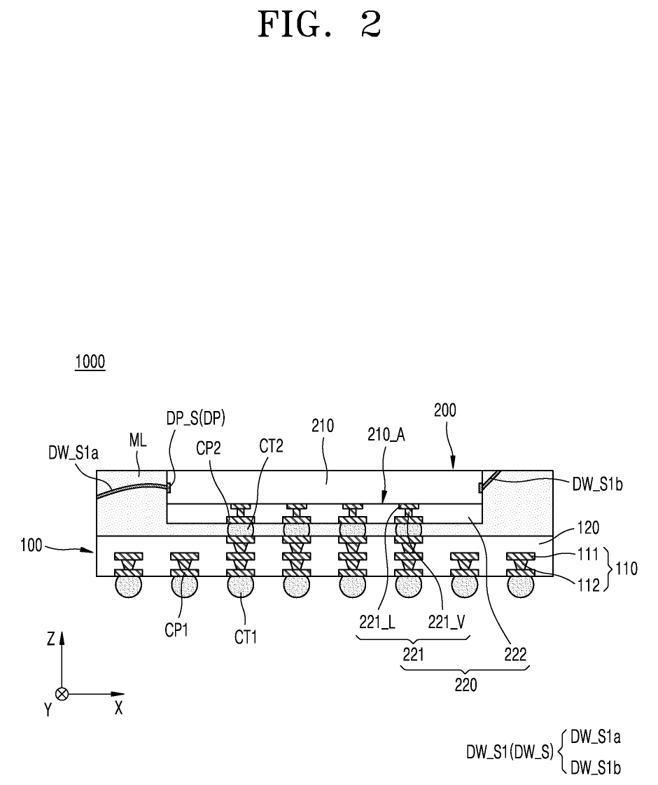

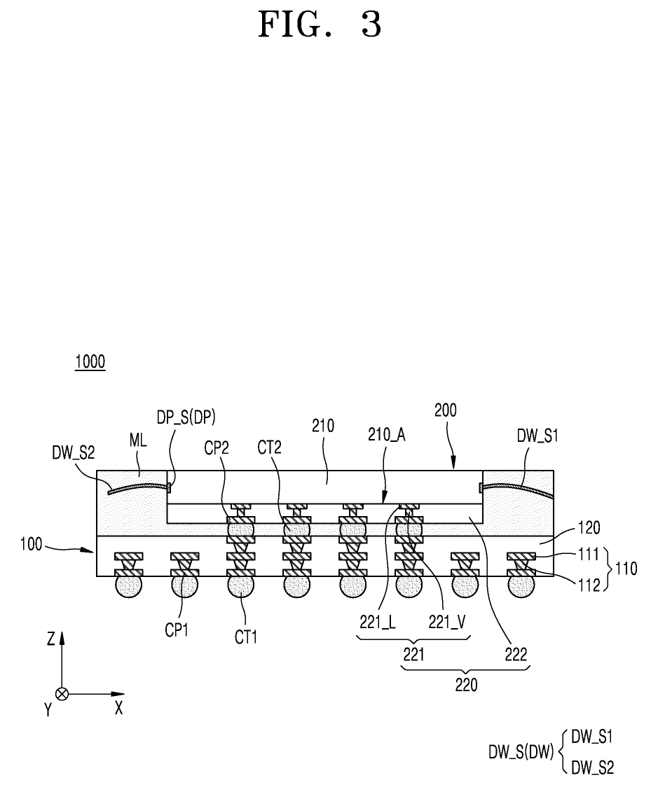

FIG. 1 is a plan view of a semiconductor package 1000 according to example embodiments. FIG. 2 is a cross-sectional view of the semiconductor package 1000 according to example embodiments. FIG. 3 is a cross-sectional view of the semiconductor package 1000 according to example embodiments. Specifically, in FIG. 1, a lower molding layer ML is illustrated as being transparent to allow visualization of a plurality of lower dummy wires DW.

Referring to FIGS. 1 to 3, the semiconductor package 1000 may include a lower redistribution structure 100, a lower semiconductor chip 200, the lower molding layer ML, and the plurality of lower dummy wires DW.

As used herein, the lower redistribution structure 100 may be referred to as a redistribution structure, the lower semiconductor chip 200 may be referred to as a semiconductor chip, the lower molding layer ML may be referred to as a molding layer, and the plurality of lower dummy wires DW may be referred to as a plurality of dummy wires.

As used herein, unless specified otherwise, a direction parallel to an upper surface of the lower redistribution structure 100 may be defined as a first lateral direction (X direction), a direction perpendicular to the upper surface of the lower redistribution structure 100 may be defined as a vertical direction (Z direction), and a direction perpendicular to the first lateral direction (X direction) and the vertical direction (Z direction) may be defined as a second lateral direction (Y direction). A lateral direction may be defined as a combination of the first lateral direction (Y direction) and the second lateral direction (X direction).

The lower redistribution structure 100 may be a redistribution layer (RDL) configured to extend input/output (I/O) terminals of the lower semiconductor chip 200 to an outer region of the lower semiconductor chip 200. However, example embodiments are not limited thereto, and the lower redistribution structure 100 may include a printed circuit board (PCB) or an interposer.

The lower redistribution structure 100 may include a lower redistribution pattern 110 including a lower redistribution via 112 and a lower redistribution line 111 and lower redistribution insulating layers 120 surrounding the lower redistribution pattern 110.

The numbers and arrangements of lower redistribution insulating layers 120, lower redistribution vias 112, and lower redistribution lines 111, which are included in the lower redistribution structure 100, are not limited to those illustrated in the drawings and may be variously changed in example embodiments.

The lower redistribution insulating layers 120 may include an insulating material, for example, a photo imageable dielectric (PID) resin. In this case, the lower redistribution insulating layers 120 may further include inorganic fillers. The lower redistribution insulating layers 120 may include the same material or different materials.

The lower redistribution pattern 110 including the lower redistribution via 112 and the lower redistribution line 111 may extend the I/O terminals (i.e., may extend electrical connections) of the lower semiconductor chip 200 to the outside. The lower redistribution line 111 may be located on at least one of an upper surface and a lower surface of the lower redistribution insulating layers 120 and extend in the lateral direction. The lower redistribution via 112 may pass through the lower redistribution insulating layers 120 and extend in the vertical direction (Z direction) and be connected to the lower redistribution line 111.

The lower redistribution via 112 may be completed filled by a conductive material. Alternatively, the conductive material may have a shape that is formed along a wall of the lower redistribution via 112. The lower redistribution pattern 110 may include a conductive material, for example, copper (Cu), aluminum (Al), silver (Ag), tin (Sn), gold (Au), nickel (Ni), lead (Pb), titanium (Ti), or an alloy thereof.

The lower redistribution structure 100 may include external connection pads CP1. The external connection pads CP1 may be located on a lower surface of the lower redistribution structure 100 and exposed to the outside of the lower redistribution structure 100. The external connection pad CP1 may be electrically connected to the lower redistribution pattern 110 of the lower redistribution structure 100.

External connection terminals CT1 may be provided on the external connection pads CP1 of the lower redistribution structure 100. For example, the external connection terminals CT1 may be adhered to the external connection pads CP1 of the lower redistribution structure 100. The external connection terminals CT1 may connect the semiconductor package 1000 to a main board of a separate electronic device on which the semiconductor package 1000 is mounted. The external connection terminals CT1 may include a conductive material, for example, at least one of solder, tin (Sn), silver (Ag), copper (Cu), and aluminum (Al). A shape of the external connection terminals CT1 may be changed to various other shapes, such as a land shape, a bump shape, a pillar shape, and a pin shape, in addition to a ball shape.

The lower semiconductor chip 200 may include a lower semiconductor substrate 210, a lower wiring structure 220, and a plurality of lower dummy pads DP.

The lower semiconductor substrate 210 may include an active surface 210_A and an inactive surface opposite to the active surface 210_A. The lower semiconductor chip 200 may be arranged on the lower redistribution structure 100 such that the active surface 210_A of the lower semiconductor substrate 210 faces the lower redistribution structure 100. For example, the lower semiconductor chip 200 may be arranged in a face-down manner on the lower redistribution structure 100.

The lower semiconductor substrate 210 may include, for example, a semiconductor material, such as silicon (Si) or germanium (Ge). Alternatively, the lower semiconductor substrate 210 may include a compound semiconductor material, such as silicon carbide (SiC), gallium arsenide (GaAs), indium arsenide (InAs), and indium phosphide (InP). The lower semiconductor substrate 210 may include a doped well, which is a conductive region. The lower semiconductor substrate 210 may have various device isolation structures, such as a shallow trench isolation (STI) structure.

A plurality of individual devices may be formed on the active surface 210_A of the lower semiconductor substrate 210. The plurality of individual devices may be the same or different types of devices. The plurality of individual devices may be electrically connected to a lower wiring pattern 221 of the lower wiring structure 220. Also, each of the plurality of individual devices may be electrically isolated from another individual device adjacent thereto by an insulating film.

In some example embodiments, the lower semiconductor chip 200 may include a logic device (i.e., a logic circuit). For instance, the lower semiconductor chip 200 may include a central processing unit (CPU) chip, a graphics processing unit (GPU) chip, or an application processor (AP). In other example embodiments, the semiconductor package 1000 may include a plurality of lower semiconductor chips 200, one of the plurality of lower semiconductor chips 200 may include a CPU chip, a GPU chip, or an AP chip, and another one thereof may include a memory semiconductor chip including a memory device.

For instance, the memory device may include a non-volatile memory device, such as flash memory, phase-change random access memory (PRAM), magnetoresistive RAM (MRAM), ferroelectric RAM (FeRAM), or resistive RAM (RRAM). In some example embodiments, the memory device may include a volatile memory device, such as dynamic RAM (DRAM) or static RAM (SRAM).

The lower wiring structure 220 may be located on the active surface 210_A of the lower semiconductor substrate 210. For example, the lower wiring structure 220 may include a back-end-of-line (BEOL) structure. The inactive surface of the lower semiconductor substrate 210 may be referred to as a back side of the lower semiconductor chip 200, and a surface spaced apart from the active surface 210_A of the lower semiconductor substrate 210, from among an upper surface and a lower surface of the lower wiring structure 220, may be referred to as a front side of the lower semiconductor chip 200.

The lower wiring structure 220 may include a lower wiring pattern 221 and a lower wiring insulating layer 222 surrounding the lower wiring pattern 221. The lower wiring pattern 221 may include lower wiring lines 221_L extending in the lateral direction and a lower wiring via 221_V extending from the lower wiring lines 221_L in the vertical direction (Z direction). The lower wiring pattern 221 may be electrically connected to a plurality of individual devices of the lower semiconductor substrate 210.

In some example embodiments, the lower wiring structure 220 may have a multilayered wiring structure including the lower wiring lines 221_L and the lower wiring via 221_V, which are located at different vertical levels. As used herein, a vertical level may denote a separation distance from a lower surface of the lower redistribution structure 100.

The lower wiring structure 220 may include lower front-side pads CP2. The lower front-side pads CP2 may be located on the lower surface of the lower wiring structure 220 and be exposed to the outside of the lower semiconductor chip 200. The lower front-side pads CP2 may be electrically connected to the lower wiring pattern 221. For example, the lower front-side pads CP2 may be located below a lowermost one of the lower wiring lines 221_L.

In some example embodiments, lower connection terminals CT2 may be adhered onto the lower front-side pads CP2 of the lower wiring structure 220. The lower connection terminals CT2 may be respectively located between the lower redistribution structure 100 and the lower front-side pads CP2. The lower connection terminals CT2 may electrically connect the lower semiconductor chip 200 to the lower redistribution structure 100.

The plurality of lower dummy pads DP may be located on outer surfaces of the lower semiconductor chip 200 and be exposed to the outside of the lower semiconductor chip 200. The plurality of lower dummy pads DP may not be electrically connected to a plurality of individual devices located on the active surface 210_A of the lower semiconductor substrate 210 of the lower semiconductor chip 200. For example, the plurality of lower dummy pads DP may be electrically insulated from the plurality of individual devices located on the active surface 210_A. The plurality of lower dummy pads DP may not be electrically connected to the lower wiring pattern 221 of the lower wiring structure 220 of the lower semiconductor chip 200. For example, the plurality of lower dummy pads DP may be electrically insulated from the lower wiring pattern 221.

The plurality of lower dummy pads DP may be located on an outer surface adjacent to points where heat is generated by the lower semiconductor chip 200, from among the outer surfaces of the lower semiconductor chip 200. For example, the plurality of lower dummy pads DP may be pads for forming the plurality of lower dummy wires DW. For example, in the semiconductor package 1000, the plurality of lower dummy pads DP and the plurality of lower dummy wires DW may be formed at points where heat is generated by the lower semiconductor chip 200, and thus, heat generated by the lower semiconductor chip 200 may be efficiently dissipated to the outside of the semiconductor package 1000.

The plurality of lower dummy pads DP may include a lateral-side lower dummy pad DP_S located on a lateral surface of the lower semiconductor substrate 210 of the lower semiconductor chip 200. For example, the lateral-side lower dummy pad DP_S may be located on the lateral surface of the lower semiconductor substrate 210 and be spaced apart from the active surface 210_A of the lower semiconductor substrate 210.

The plurality of lower dummy wires DW may be adhered to the lower semiconductor chip 200. For example, a first end of each of the plurality of lower dummy wires DW may be in contact with one of the plurality of lower dummy pads DP of the lower semiconductor chip 200, and a second end of each of the plurality of lower dummy wires DW may be located apart from the lower semiconductor chip 200 and the lower redistribution structure 100. The second end of the lower dummy wire DW may be an end opposite to the first end of the lower dummy wire DW.

For example, the plurality of lower dummy wires DW may not be electrically connected to (i.e., may be electrically isolated from) the lower semiconductor chip 200 and the lower redistribution structure 100. In some example embodiments, the plurality of lower dummy wires DW may be located inside the lower molding layer ML.

For instance, the plurality of lower dummy wires DW may include copper (Cu), aluminum (Al), silver (Ag), tin (Sn), gold (Au), nickel (Ni), lead (Pb), titanium (Ti), or an alloy thereof. As an example, the plurality of lower dummy wires DW may include copper.

The lower molding layer ML may be located on the lower redistribution structure 100 and be in contact with a lateral surface of the lower semiconductor chip 200. The lower molding layer ML may be in contact with outer surfaces of the plurality of lower dummy wires DW. The lower molding layer ML may protect the lower semiconductor chip 200 from external impact.

For example, an upper surface of the lower molding layer ML may be coplanar with an upper surface of the lower semiconductor chip 200. For example, the upper surface of the lower semiconductor chip 200 may be exposed to the outside of the semiconductor package 1000. For example, the upper surface of the lower semiconductor chip 200 may be exposed to the outside of the semiconductor package 1000, and thus, heat generated by the lower semiconductor chip 200 may be efficiently dissipated to the outside.

The lower molding layer ML may include epoxy-based materials, thermosetting materials, thermoplastic materials, etc. For instance, the lower molding layer ML may include an Ajinomoto build-up film (ABF), FR-4, bismaleimide triazine (BT), an epoxy molding compound (EMC), etc.

In some example embodiments, a heat transfer coefficient of the plurality of lower dummy wires DW may be higher than a heat transfer coefficient of the lower molding layer ML. For example, because the plurality of lower dummy wires DW has a higher heat transfer coefficient than the lower molding layer ML, the plurality of lower dummy wires DW may transfer heat dissipated by the lower semiconductor chip 200 to the outside of the semiconductor package 1000 faster than the lower molding layer ML.

The plurality of lower dummy wires DW may further include a lateral-side lower dummy wire DW_S. A first end of the lateral-side lower dummy wire DW_S may be in contact with the lateral-side lower dummy pad DP_S of the lower semiconductor chip 200. The lateral-side lower dummy wire DW_S may include an exposed lateral-side lower dummy wire DW_S1 and a buried lateral-side lower dummy wire DW_S2.

Referring to FIG. 2, a first end of the exposed lateral-side lower dummy wire DW_S1 may be in contact with the lateral-side lower dummy pad DP_S of the lower semiconductor chip 200, and a second end of the exposed lateral-side lower dummy wire DW_S1 may be coplanar with an outer surface of the lower molding layer ML. For example, the second end of the exposed lateral-side lower dummy wire DW_S1 may be coplanar with a lateral surface or the upper surface of the lower molding layer ML. The second end of the exposed lateral-side lower dummy wire DW_S1 may be exposed to the outside of the semiconductor package 1000.

The exposed lateral-side lower dummy wire DW_S1 may be exposed to the outside of the lower molding layer ML. The exposed lateral-side lower dummy wire DW_S1 may provide a path to dissipate, to the outside of the semiconductor package 1000, heat from the lower semiconductor chip 200 to the outside of the semiconductor package 1000 which otherwise would be insulated due to a relatively low heat transfer coefficient of the lower molding layer ML.

In some example embodiments, the exposed lateral-side lower dummy wire DW_S1 may include a first exposed lateral-side lower dummy wire DW_S1a and a second exposed lateral-side lower dummy wire DW_S1b. A second end of the first exposed lateral-side lower dummy wire DW_S1a may be coplanar with the lateral surface of the lower molding layer ML, and a second end of the second exposed lateral-side lower dummy wire DW_S1b may be coplanar with the upper surface of the lower molding layer ML. In some example embodiments, the first exposed lateral-side lower dummy wire DW_S1a may extend in a parabolic shape.

For example, the first exposed lateral-side lower dummy wire DW_S1a may extend from the lower semiconductor chip 200 to the lateral surface of the lower molding layer ML, and the second exposed lateral-side lower dummy wire DW_S1b may extend from the lower semiconductor chip 200 to the upper surface of the lower molding layer ML.

For example, the second end of the first exposed lateral-side lower dummy wire DW_S1a may be at a lower vertical level than the lateral-side lower dummy pad DP_S. The second end of the second exposed lateral-side lower dummy wire DW_S1b may be at a higher level than the lateral-side lower dummy pad DP_S.

Referring to FIG. 3, a first end of the buried lateral-side lower dummy wire DW_S2 may be in contact with the lateral-side lower dummy pad DP_S of the lower semiconductor chip 200, and a second end of the buried lateral-side lower dummy wire DW_S2 may be located inside the lower molding layer ML. For example, the buried lateral-side lower dummy wire DW_S2 may not be exposed to the outside of the semiconductor package 1000.

The buried lateral-side lower dummy wire DW_S2 may extend from the lower semiconductor chip 200 to a first portion of the lower molding layer ML, which is relatively far away from the lower semiconductor chip 200. The buried lateral-side lower dummy wire DW_S2 may relatively quickly transfer heat generated by the lower semiconductor chip 200 to the first portion. Accordingly, a temperature of the lower molding layer ML may be evenly increased, thereby increasing heat dissipation efficiency of the semiconductor package 1000.

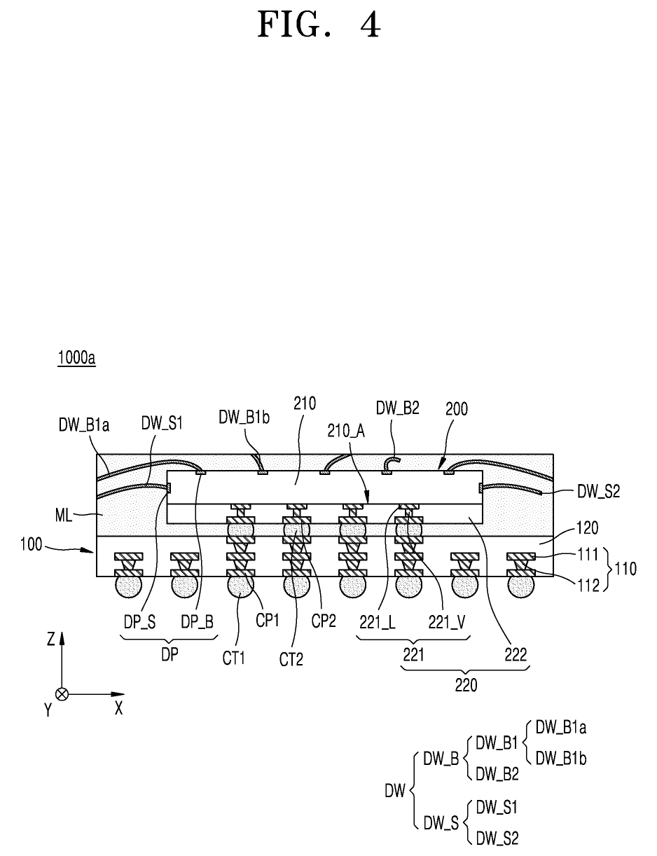

FIG. 4 is a cross-sectional view of a semiconductor package 1000a according to example embodiments.

Most of components included in the semiconductor package 1000a described below and materials forming the components are substantially the same as or similar to those described above with reference to FIG. 2. Thus, for brevity, the description below will focus on differences between the semiconductor package 1000a of FIG. 4 and the semiconductor package 1000 described above with reference to FIG. 2.

Referring to FIG. 4, the semiconductor package 1000a may include a lower redistribution structure 100, a lower semiconductor chip 200, a plurality of lower dummy wires DW, and a lower molding layer ML.

The lower semiconductor chip 200 may include a plurality of lower dummy pads DP. The plurality of lower dummy pads DP may include a lateral-side lower dummy pad DP_S and a back-side lower dummy pad DP_B. The lateral-side lower dummy pad DP_S may be located on a lateral surface of the lower semiconductor substrate 210 of the lower semiconductor chip 200. The back-side lower dummy pad DP_B may be located on the inactive surface of the lower semiconductor substrate 210 of the lower semiconductor chip 200.

The lower molding layer ML may be located on the lower redistribution structure 100 and be in contact with the lower semiconductor chip 200 and the plurality of lower dummy wires DW. The lower molding layer ML may cover an upper surface of the lower semiconductor chip 200. For example, an upper surface of the lower molding layer ML may be at a higher vertical level than the upper surface of the lower semiconductor chip 200.

A first end of each of the plurality of lower dummy wires DW may be in contact with one of the plurality of lower dummy pads DP of the lower semiconductor chip 200, and a second end of each of the plurality of lower dummy wires DW may be located apart from the lower semiconductor chip 200 and the lower redistribution structure 100. The plurality of lower dummy wires DW may include a lateral-side lower dummy wire DW_S and a back-side lower dummy wire DW_B. The lateral-side lower dummy wire DW_S may substantially be the same as described above with reference to FIGS. 1 to 3.

A first end of the back-side lower dummy wire DW_B may be in contact with the back-side lower dummy pad DP_B of the lower semiconductor chip 200. The back-side lower dummy wire DW_B may include an exposed back-side lower dummy wire DW_B1 and a buried back-side lower dummy wire DW_B2.

A first end of the exposed back-side lower dummy wire DW_B1 may be in contact with the back-side lower dummy pad DP_B of the lower semiconductor chip 200, and a second end of the exposed back-side lower dummy wire DW_B1 may be coplanar with an outer surface of the lower molding layer ML. For example, the second end of the exposed back-side lower dummy wire DW_B1 may be coplanar with a lateral surface or the upper surface of the lower molding layer ML. The second end of the exposed back-side lower dummy wire DW_B1 may be exposed to the outside of the semiconductor package 1000.

The exposed back-side lower dummy wire DW_B1 may be exposed to the outside of the lower molding layer ML. The exposed back-side lower dummy wire DW_B1 may provide a path to dissipate, to the outside of the semiconductor package 1000, heat from the lower semiconductor chip 200 to the outside of the semiconductor package 1000, which otherwise would be insulated due to a relatively low heat transfer coefficient of the lower molding layer ML.

In some example embodiments, the exposed back-side lower dummy wire DW_B1 may include a first exposed back-side lower dummy wire DW_B1a and a second exposed back-side lower dummy wire DW_B1b. A second end of the first exposed back-side lower dummy wire DW_B1a may be coplanar with the lateral surface of the lower molding layer ML, and a second end of the second exposed back-side lower dummy wire DW_B1b may be coplanar with the upper surface of the lower molding layer ML. In some example embodiments, the first exposed back-side lower dummy wire DW_B1a may extend in a parabolic shape.

For example, the first exposed back-side lower dummy wire DW_B1a may extend from the lower semiconductor chip 200 to the lateral surface of the lower molding layer ML, and the second exposed back-side lower dummy wire DW_B1b may extend from the lower semiconductor chip 200 to the upper surface of the lower molding layer ML.

For example, the second end of the first exposed back-side lower dummy wire DW_B1a may be at a lower vertical level than the back-side lower dummy pad DP_B. The second end of the second exposed back-side lower dummy wire DW_B1b may be at a higher vertical level than the back-side lower dummy pad DP_B.

A first end of the buried back-side lower dummy wire DW_B2 may be in contact with the back-side lower dummy pad DP_B of the lower semiconductor chip 200, and a second end of the buried back-side lower dummy wire DW_B2 may be located inside the lower molding layer ML. For example, the buried back-side lower dummy wire DW_B2 may not be exposed to the outside of the semiconductor package 1000.

The buried back-side lower dummy wire DW_B2 may extend from the lower semiconductor chip 200 to a first portion of the lower molding layer ML, which is relatively far away from the lower semiconductor chip 200. The buried back-side lower dummy wire DW_B2 may relatively quickly transfer heat generated by the lower semiconductor chip 200 to the first portion. Accordingly, a temperature of the lower molding layer ML may be evenly increased, thereby increasing heat dissipation efficiency of the semiconductor package 1000.

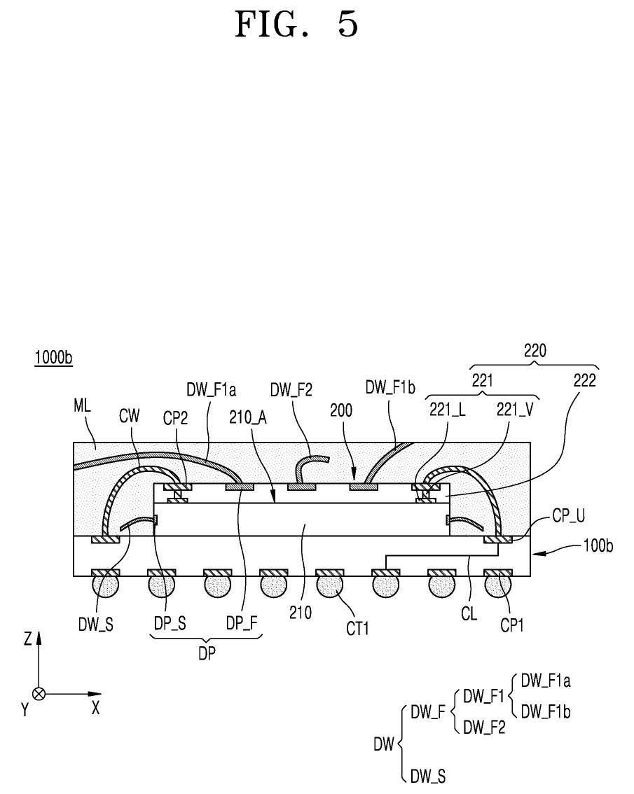

FIG. 5 is a cross-sectional view of a semiconductor package 1000b according to example embodiments.

Most of components included in the semiconductor package 1000b described below and materials forming the components are substantially the same as or similar to those described above with reference to FIG. 2. Thus, for brevity, the description below will focus on differences between the semiconductor package 1000b of FIG. 5 and the semiconductor package 1000 described above with reference to FIG. 2.

Referring to FIG. 5, the semiconductor package 1000b may include a lower redistribution structure 100b, a lower semiconductor chip 200, a plurality of lower dummy wires DW, a plurality of lower connection wires CW, and a lower molding layer ML.

The lower redistribution structure 100b may include a lower chip connection pad CP_U and an external connection pad CP1. The lower chip connection pad CP_U may be located on an upper surface of the lower redistribution structure 100b, and the external connection pad CP1 may be located on a lower surface of the lower redistribution structure 100b. For example, the lower redistribution structure 100b may include an inner wiring CL configured to electrically connect the lower chip connection pad CP_U to the external connection pad CP1.

The lower semiconductor chip 200 may be located on the lower redistribution structure 100b such that the inactive surface of the lower semiconductor substrate 210 faces the lower redistribution structure 100b. For example, the lower semiconductor chip 200 may be arranged in a face-up manner on the lower redistribution structure 100b. For example, the lower semiconductor chip 200 may be arranged on the lower redistribution structure 100b such that a lower wiring structure 220 faces upward in a vertical direction (Z direction). For example, the lower semiconductor chip 200 may be arranged in a region of the upper surface of the lower redistribution structure 100b, which does not overlap the lower chip connection pad CP_U.

The plurality of lower dummy pads DP of the lower semiconductor chip 200 may include a lateral-side lower dummy pad DP_S and a front-side lower dummy pad DP_F. The front-side lower dummy pad DP_F may be located on a front surface of the lower semiconductor chip 200. For example, the front-side lower dummy pad DP_F may be located on one surface of the lower wiring structure 220 of the lower semiconductor chip 200.

The plurality of lower connection wires CW may electrically connect the lower semiconductor chip 200 to the lower redistribution structure 100b. For example, a first end of each of the plurality of lower connection wires CW may be in contact with the lower front-side pad CP2 of the lower wiring structure 220 of the lower semiconductor chip 200, and a second end of each of the plurality of lower connection wires CW may be in contact with the lower chip connection pad CP_U of the lower redistribution structure 100b.

For example, the plurality of lower connection wires CW may include copper (Cu), aluminum (Al), silver (Ag), tin (Sn), gold (Au), nickel (Ni), lead (Pb), titanium (Ti), or an alloy thereof. As an example, the plurality of lower connection wires CW may include gold. In some example embodiments, a constituent material of the plurality of lower connection wires CW may be different from a constituent material of the plurality of lower dummy wires DW.

The plurality of lower dummy wires DW may include a lateral-side lower dummy wire DW_S and a front-side lower dummy wire DW_F. A first end of the front-side lower dummy wire DW_F may be in contact with the front-side lower dummy pad DP_F of the lower semiconductor chip 200. The front-side lower dummy wire DW_F may include an exposed front-side lower dummy wire DW_F1 and a buried front-side lower dummy wire DW_F2.

A first end of the exposed front-side lower dummy wire DW_F1 may be in contact with the front-side lower dummy pad DP_F of the lower semiconductor chip 200, and a second end of the exposed front-side lower dummy wire DW_F1 may be coplanar with an outer surface of the lower molding layer ML. For example, the second end of the exposed front-side lower dummy wire DW_F1 may be coplanar with a lateral surface or an upper surface of the lower molding layer ML. The second end of the exposed front-side lower dummy wire DW_F1 may be exposed to the outside of the semiconductor package 1000.

The exposed front-side lower dummy wire DW_F1 may be exposed to the outside of the lower molding layer ML. The exposed front-side lower dummy wire DW_F1 may provide a path to dissipate, to the outside of the semiconductor package 1000, heat from the lower semiconductor chip 200 to the outside of the semiconductor package 1000, which otherwise would be insulated due to a relatively low heat transfer coefficient of the lower molding layer ML.

In some example embodiments, the exposed front-side lower dummy wire DW_F1 may include a first exposed front-side lower dummy wire DW_F1a and a second exposed front-side lower dummy wire DW_F1b. A second end of the first exposed front-side lower dummy wire DW_F1a may be coplanar with the lateral surface of the lower molding layer ML, and a second end of the second exposed front-side lower dummy wire DW_F1b may be coplanar with the upper surface of the lower molding layer ML. In some example embodiments, the first exposed front-side lower dummy wire DW_F1a may extend in a parabolic shape.

For example, the first exposed front-side lower dummy wire DW_F1a may extend from the lower semiconductor chip 200 to the lateral surface of the lower molding layer ML, and the second exposed front-side lower dummy wire DW_F1b may extend from the lower semiconductor chip 200 to the upper surface of the lower molding layer ML.

For example, the second end of the first exposed front-side lower dummy wire DW_F1a may be at a lower vertical level than the front-side lower dummy pad DP_F. The second end of the second exposed front-side lower dummy wire DW_F1b may be at a higher vertical level than the front-side lower dummy pad DP_F.

A first end of the buried front-side lower dummy wire DW_F2 may be in contact with the front-side lower dummy pad DP_F of the lower semiconductor chip 200, and a second end of the buried front-side lower dummy wire DW_F2 may be located inside the lower molding layer ML. For example, the buried front-side lower dummy wire DW_F2 may not be exposed to the outside of the semiconductor package 1000.

The buried front-side lower dummy wire DW_F2 may extend from the lower semiconductor chip 200 to a first portion of the lower molding layer ML, which is relatively far away from the lower semiconductor chip 200. The buried front-side lower dummy wire DW_F2 may relatively quickly transfer heat generated by the lower semiconductor chip 200 to the first portion. Accordingly, a temperature of the lower molding layer ML may be evenly increased, thereby increasing heat dissipation efficiency of the semiconductor package 1000.

The lower molding layer ML may be located on the lower redistribution structure 100 and be in contact with the lower semiconductor chip 200 and the plurality of lower dummy wires DW. The lower molding layer ML may cover the upper surface of the lower semiconductor chip 200. For example, the upper surface of the lower molding layer ML may be at a higher vertical level than an upper surface of the lower semiconductor chip 200.

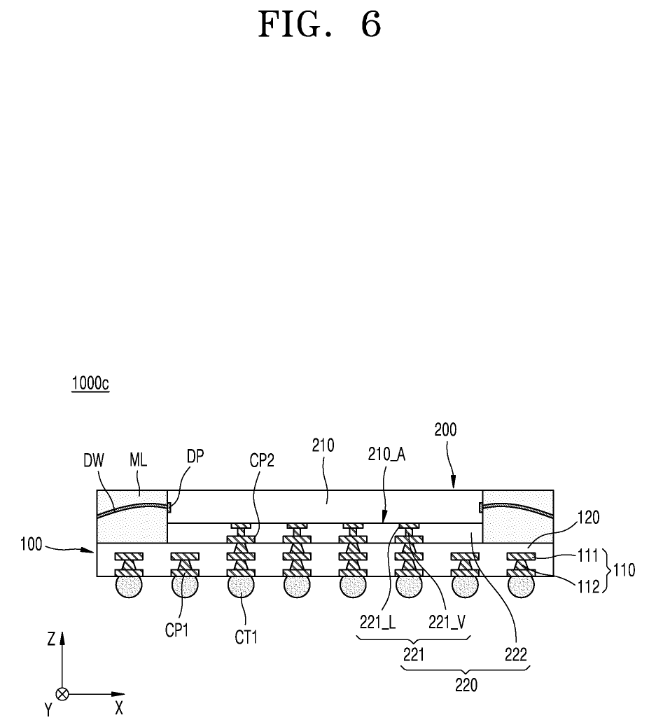

FIG. 6 is a cross-sectional view of a semiconductor package 1000c according to example embodiments.

Most of components included in the semiconductor package 1000c described below and materials forming the components are substantially the same as or similar to those described above with reference to FIG. 2. Thus, for brevity, the description below will focus on differences between the semiconductor package 1000c of FIG. 6 and the semiconductor package 1000 described above with reference to FIG. 2.

Referring to FIG. 6, the semiconductor package 1000c may include a lower redistribution structure 100, a lower semiconductor chip 200, a plurality of lower dummy wires DW, and a lower molding layer ML.

The lower semiconductor chip 200 may be mounted on an upper surface of the lower redistribution structure 100. For example, a lower wiring structure 220 of the lower semiconductor chip 200 may be in contact with the lower redistribution structure 100. For example, the lower semiconductor chip 200 may be electrically connected to the lower redistribution structure 100 without the lower connection terminals (refer to CT2 in FIG. 2).

In some example embodiments, the semiconductor package 1000c may be manufactured in a chip-first manner. For example, the lower semiconductor chip 200 may be mounted on a carrier substrate such that the inactive surface of the lower semiconductor substrate 210 faces the carrier substrate, and then, the lower redistribution structure 100 may be formed on the lower wiring structure 220 of the lower semiconductor chip 200.

In some example embodiments, a lower redistribution via 112 of a lower redistribution pattern 110 of the lower redistribution structure 100 may have a greater lateral width in a direction away from the lower semiconductor chip 200.

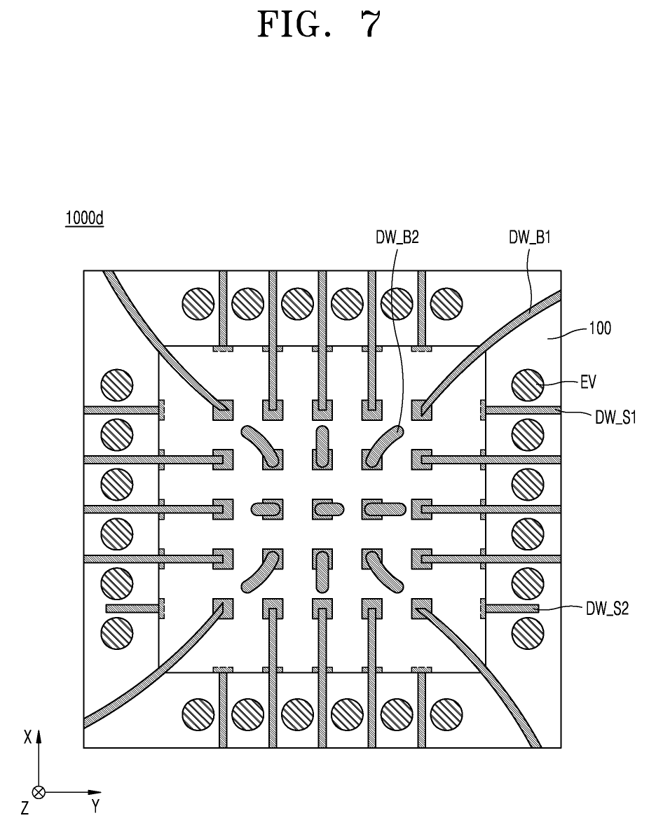

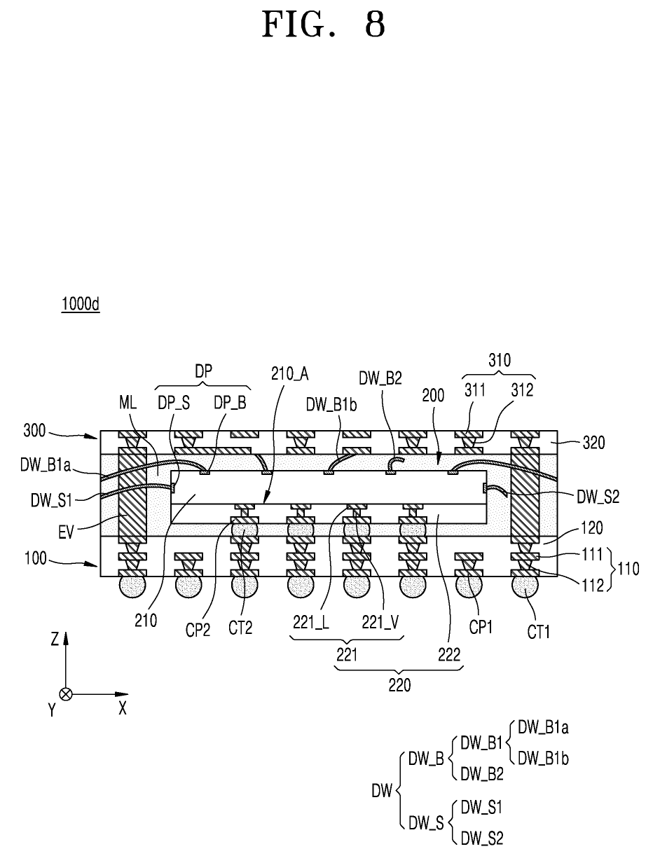

FIG. 7 is a plan view of a semiconductor package 1000d according to example embodiments. FIG. 8 is a cross-sectional view of the semiconductor package 1000d according to example embodiments. Specifically, in FIG. 7, a lower molding layer ML and an upper redistribution structure 300 are illustrated as transparent to allow visualization of a plurality of lower dummy wires DW.

Most of components included in the semiconductor package 1000d described below and materials forming the components are substantially the same as or similar to those described above with reference to FIG. 4. Thus, for brevity, the description below will focus on differences between the semiconductor package 1000d of FIGS. 7 and 8 and the semiconductor package 1000a described above with reference to FIG. 4.

Referring to FIGS. 7 and 8, the semiconductor package 1000d may include a lower redistribution structure 100, a lower semiconductor chip 200, the lower molding layer ML, a plurality of lower through vias EV, a plurality of lower dummy wires DW, and the upper redistribution structure 300.

The plurality of lower through vias EV may be located on the lower redistribution structure 100 and pass through the lower molding layer ML. For example, the plurality of lower through vias EV may extend from an upper surface of the lower molding layer ML to a lower surface thereof.

For example, the plurality of lower through vias EV may electrically connect the lower redistribution structure 100 and the upper redistribution structure 300. For example, a lower surface of each of the plurality of lower through vias EV may be in contact with a lower redistribution pattern of the lower redistribution structure 100, and an upper surface of each of the plurality of lower through vias EV may be in contact with an upper redistribution pattern 310 of the upper redistribution structure 300.

In some example embodiments, the plurality of lower dummy wires DW may be located apart from the plurality of lower through vias EV. For example, the lower molding layer ML may extend between the plurality of lower dummy wires DW and the plurality of lower through vias EV, and thus, the plurality of lower dummy wires DW may be insulated from the plurality of lower through vias EV.

For example, the plurality of lower through vias EV may include a conductive material, for example, copper (Cu), aluminum (Al), silver (Ag), tin (Sn), gold (Au), nickel (Ni), lead (Pb), titanium (Ti), or an alloy thereof.

The upper redistribution structure 300 may be located on the lower molding layer ML and the plurality of lower through vias EV. The upper redistribution structure 300 may include the upper redistribution pattern 310 including an upper redistribution via 312 and an upper redistribution line 311 and upper redistribution insulating layers 320 surrounding the upper redistribution pattern 310.

The numbers and arrangements of upper redistribution insulating layers 320, upper redistribution vias 312, and upper redistribution lines 311, which are included in the upper redistribution structure 300, are not limited to those illustrated in the drawings and may be variously changed in example embodiments.

The upper redistribution insulating layers 320 may include an insulating material, for example, a PID resin. In this case, the upper redistribution insulating layers 320 may further include inorganic fillers. The upper redistribution insulating layers 320 may include the same material or different materials.

The upper redistribution line 311 may be located on at least one of an upper surface and a lower surface of the upper redistribution insulating layers 320 and extend in a lateral direction. The upper redistribution via 312 may pass through the upper redistribution insulating layers 320, extend in a vertical direction (Z direction), and be connected to the upper redistribution line 311.

The upper redistribution via 312 may be completed filled by a conductive material. Alternatively, the conductive material may have a shape formed along a wall of the upper redistribution via 312. The upper redistribution pattern 310 may include a conductive material, for example, copper (Cu), aluminum (Al), silver (Ag), tin (Sn), gold (Au), nickel (Ni), lead (Pb), titanium (Ti), or an alloy thereof.

For example, a width of the upper redistribution structure 300, a width of the lower molding layer ML, and a width of the lower redistribution structure 100 may be equal to each other. For example, lateral surfaces of the upper redistribution structure 300, the lower molding layer ML, and the lower redistribution structure 100 may be aligned with each other in the vertical direction (Z direction).

In some example embodiments, some of the plurality of lower dummy wires DW may be in contact with the upper redistribution structure 300. For example, an exposed lateral-side lower dummy wire DW_S1 and an exposed back-side lower dummy wire DW_B1 of the plurality of lower dummy wires DW may be in contact with the upper redistribution insulating layers 320 of the upper redistribution structure 300.

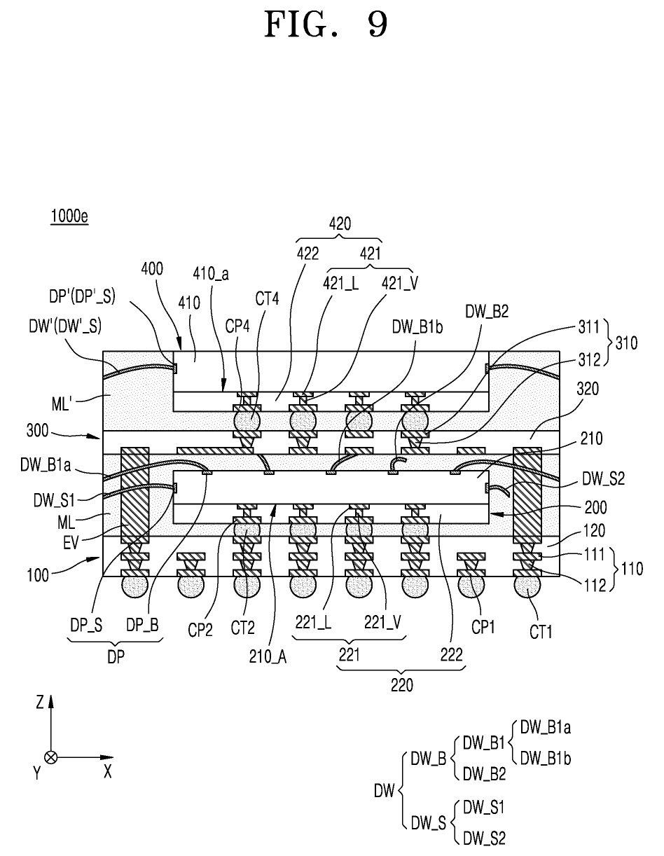

FIG. 9 is a cross-sectional view of a semiconductor package 1000e according to example embodiments.

Most of components included in the semiconductor package 1000e described below and materials forming the components are substantially the same as or similar to those described above with reference to FIG. 8. Thus, for brevity, the description below will focus on differences between the semiconductor package 1000e of FIG. 9 and the semiconductor package 1000d described above with reference to FIG. 8.

For example, the semiconductor package 1000e of FIG. 9 may pertain to an example embodiment in which an upper semiconductor chip 400 is mounted in a flip-chip manner on the semiconductor package 1000d of FIG. 8. For instance, the semiconductor package 1000e of FIG. 9 may be a package in which the lower semiconductor chip 200, the plurality of lower dummy wires DW, and a lower molding layer ML of FIG. 1 are formed on the semiconductor package 1000d of FIG. 8.

Referring to FIG. 9, the semiconductor package 1000e may include a lower redistribution structure 100, the lower semiconductor chip 200, the lower molding layer ML, a plurality of lower through vias EV, a plurality of lower dummy wires DW, an upper redistribution structure 300, the upper semiconductor chip 400, an upper molding layer ML’, and a plurality of upper dummy wires DW’.

The upper semiconductor chip 400 may include an upper semiconductor substrate 410, an upper wiring structure 420, and a plurality of upper dummy pads DP’.

The upper semiconductor substrate 410 may include an active surface 410_A and an inactive surface opposite to the active surface 410_A. The upper semiconductor chip 400 may be arranged on the upper redistribution structure 300 such that the active surface 410_A of the upper semiconductor substrate 410 faces the upper redistribution structure 300. For example, the upper semiconductor chip 400 may be arranged in a face-down manner on the upper redistribution structure 300.

The upper semiconductor substrate 410 may include, for example, a semiconductor material, such as silicon (Si) or germanium (Ge). Alternatively, the upper semiconductor substrate 410 may include a compound semiconductor material, such as silicon carbide (SiC), gallium arsenide (GaAs), indium arsenide (InAs), and indium phosphide (InP). The upper semiconductor substrate 410 may include a doped well, which is a conductive region. The upper semiconductor substrate 410 may have various device isolation structures, such as an STI structure.

A plurality of individual devices of various kinds may be formed on the active surface 410_A of the upper semiconductor substrate 410. The plurality of individual devices may be electrically connected to the upper wiring pattern 421 of the upper wiring structure 420. In addition, each of the plurality of individual devices may be electrically isolated from another individual device adjacent thereto by an insulating film.

In some example embodiments, the upper semiconductor chip 400 may include a logic device. For instance, the upper semiconductor chip 400 may include a CPU chip, a GPU chip, or an AP. In other example embodiments, when the semiconductor package 1000 includes a plurality of upper semiconductor chips 400, one of the plurality of upper semiconductor chips 400 may include a CPU chip, a GPU chip, or an AP chip, and another one thereof may include a memory semiconductor chip including a memory device.

In some example embodiments, the lower semiconductor chip 200 and the upper semiconductor chip 400 may include different types of semiconductor chips.

The upper wiring structure 420 may be located on the active surface 410_A of the upper semiconductor substrate 410. For example, the upper wiring structure 420 may include a BEOL structure. The inactive surface of the upper semiconductor substrate 410 may be referred to as a back side of the upper semiconductor chip 400, and a surface spaced apart from the active surface 410_A of the upper semiconductor substrate 410, from among an upper surface and a lower surface of the upper wiring structure 420, may be referred to as a front side of the upper semiconductor chip 400.

The upper wiring structure 420 may include an upper wiring pattern 421 and a lower wiring insulating layer 422 surrounding the upper wiring pattern 421. The upper wiring pattern 421 may include upper wiring lines 421_L extending in a lateral direction and an upper wiring via 421_V extending from the upper wiring lines 421_L in a vertical direction (Z direction). The upper wiring pattern 421 may be electrically connected to the plurality of individual devices of the upper semiconductor substrate 410.

In some example embodiments, the upper wiring structure 420 may have a multilayered wiring structure including the upper wiring lines 421_L and the upper wiring via 421_V, which are located at different vertical levels.

The upper wiring structure 420 may include upper front-side pads CP4. The upper front-side pads CP4 may be located on the lower surface of the upper wiring structure 420 and be exposed to the outside of the upper semiconductor chip 400. The upper front-side pad CP4 may be electrically connected to the upper wiring pattern 421. For example, the upper front-side pad CP4 may be located below a lowermost one of the upper wiring lines 421_L.

In some example embodiments, upper connection terminals CT4 may be adhered to the upper front-side pads CP4 of the upper wiring structure 420. The upper connection terminals CT4 may be respectively located between the upper redistribution structure 300 and the upper front-side pads CP4. The upper connection terminals CT4 may electrically connect the upper semiconductor chip 400 to the upper redistribution structure 300.

The plurality of upper dummy pads DP’ may be located on outer surfaces of the upper semiconductor chip 400 and be exposed to the outside of the upper semiconductor chip 400. The plurality of upper dummy pads DP’ may not be electrically connected to (i.e., may be electrically isolated from) the plurality of individual devices located on the active surface 410_A of the upper semiconductor substrate 410 of the upper semiconductor chip 400. The plurality of upper dummy pads DP’ may not be electrically connected to (i.e., may be electrically isolated from) the upper wiring pattern 421 of the upper wiring structure 420 of the upper semiconductor chip 400.

The plurality of upper dummy pads DP’ may be located on an outer surface adjacent to points where heat is generated by the upper semiconductor chip 400, from among the outer surfaces of the upper semiconductor chip 400. For example, the plurality of upper dummy pads DP’ may be pads for forming the plurality of upper dummy wires DW’.

For example, in the semiconductor package 1000, the upper dummy pads DP’ and the upper dummy wires DW’ may be formed at points where heat is generated by the upper semiconductor chip 400, and thus, heat generated by the upper semiconductor chip 400 may be efficiently dissipated to the outside of the semiconductor package 1000.

The plurality of upper dummy pads DP’ may include a lateral-side upper dummy pad DP’_S located on a lateral surface of the upper semiconductor substrate 410 of the upper semiconductor chip 400. For example, the lateral-side upper dummy pad DP’_S may be located on the lateral surface of the upper semiconductor substrate 410 and be apart from the active surface 410_A of the upper semiconductor substrate 410.

However, example embodiments are not limited thereto, and the plurality of upper dummy pads DP’ of the upper semiconductor chip 400 may substantially be the same as the plurality of lower dummy pads DP of the lower semiconductor chip 200 described above with reference to FIGS. 2 to 4.

The plurality of upper dummy wires DW’ may be adhered to the upper semiconductor chip 400. For example, a first end of each of the plurality of upper dummy wires DW’ may be in contact with one of the plurality of upper dummy pads DP’ of the upper semiconductor chip 400, and a second end of each of the plurality of upper dummy wires DW’ may be spaced apart from the upper semiconductor chip 400 and the upper redistribution structure 300. The second end of the upper dummy wire DW’ may be an end opposite to the first end of the upper dummy wire DW’.

For example, the plurality of upper dummy wires DW’ may not be electrically connected to (i.e., may be electrically isolated from) the upper semiconductor chip 400 and the upper redistribution structure 300. In some example embodiments, the plurality of upper dummy wires DW’ may be located inside the upper molding layer ML’.

In some example embodiments, the plurality of upper dummy wires DW’ may include a lateral-side upper dummy wire DW’_S. A first end of the lateral-side upper dummy wire DW’_S may be in contact with the lateral-side upper dummy pad DP’_S of the upper semiconductor chip 400.

However, example embodiments are not limited thereto, and the plurality of upper dummy wires DW’ may substantially be the same as the plurality of lower dummy wires DW described above with reference to FIGS. 2 to 4.

For instance, the plurality of upper dummy wires DW’ may include copper (Cu), aluminum (Al), silver (Ag), tin (Sn), gold (Au), nickel (Ni), lead (Pb), titanium (Ti), or an alloy thereof. As an example, the plurality of upper dummy wires DW’ may include copper.

The upper molding layer ML’ may be located on the upper redistribution structure 300 and be in contact with a lateral surface of the upper semiconductor chip 400. The upper molding layer ML’ may be in contact with outer surfaces of the plurality of upper dummy wires DW’. The upper molding layer ML’ may protect the upper semiconductor chip 400 from external impact.

In some example embodiments, an upper surface of the upper molding layer ML’ may be coplanar with an upper surface of the upper semiconductor chip 400. However, example embodiments are not limited thereto, and the upper molding layer ML’ may cover the upper surface of the upper semiconductor chip 400, like the lower molding layer ML.

The upper molding layer ML’ may include epoxy-based materials, thermosetting materials, thermoplastic materials, etc. For instance, the upper molding layer ML’ may include an ABF, FR-4, BT, an EMC, etc.

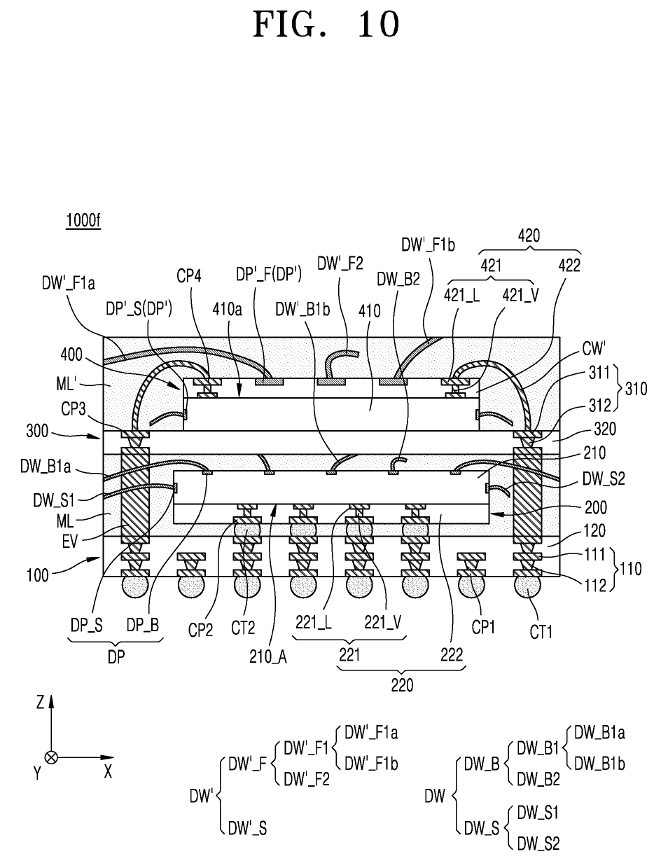

FIG. 10 is a cross-sectional view of a semiconductor package 1000f according to example embodiments.

Most of components included in the semiconductor package 1000f described below and materials forming the components are substantially the same as or similar to those described above with reference to FIG. 9. Thus, for brevity, the description below will focus on differences between the semiconductor package 1000f of FIG. 10 and the semiconductor package 1000e described above with reference to FIG. 9.

For example, the semiconductor package 1000f of FIG. 10 may pertain to an example embodiment in which an upper semiconductor chip 400 is mounted on the semiconductor package 1000d of FIG. 8 by using a wire-bonding method. For instance, the semiconductor package 1000f of FIG. 10 may be a package in which the lower semiconductor chip 200, the plurality of lower connection wires CW, the plurality of lower dummy wires DW, and the lower molding layer ML of FIG. 5 are formed on the semiconductor package 1000d of FIG. 8.

Referring to FIG. 10, the semiconductor package 1000f may include a lower redistribution structure 100, the lower semiconductor chip 200, the lower molding layer ML, a plurality of lower through vias EV, a plurality of lower dummy wires DW, an upper redistribution structure 300, the upper semiconductor chip 400, an upper molding layer ML’, a plurality of upper connection wires CW’, and a plurality of upper dummy wires DW’.

The upper semiconductor chip 400 may be arranged on the upper redistribution structure 300 such that the inactive surface of the upper semiconductor substrate 410 faces the upper redistribution structure 300. For example, the upper semiconductor chip 400 may be arranged in a face-up manner on the upper redistribution structure 300. For example, the upper semiconductor chip 400 may be arranged on the upper redistribution structure 300 such that a lower wiring structure 220 faces upward in a vertical direction (Z direction).

For example, the upper redistribution structure 300 may further include an upper chip connection pad CP3, which is located on an upper surface of the upper redistribution structure 300 and is exposed to the outside of the upper redistribution structure 300. For example, a lateral surface and a lower surface of the upper chip connection pad CP3 may be covered by upper redistribution insulating layers 320. For example, the upper chip connection pad CP3 may be electrically connected to an upper redistribution pattern 310. For example, the upper chip connection pad CP3 may not overlap the upper semiconductor chip 400 in the vertical direction (Z direction).

The plurality of upper dummy pads DP’ of the upper semiconductor chip 400 may include a lateral-side upper dummy pad DP’_S and a front-side upper dummy pad DP’_F. The front-side upper dummy pad DP’_F may be located on a front side of the upper semiconductor chip 400. For example, the front-side upper dummy pad DP’_F may be located on one surface of an upper wiring structure 420 of the upper semiconductor chip 400.

The plurality of upper connection wires CW’ may electrically connect the upper semiconductor chip 400 to a lower redistribution structure 100b. For example, a first end of each of the plurality of upper connection wires CW’ may be in contact with a lower front-side pad CP2 of the upper wiring structure 420 of the upper semiconductor chip 400, and a second end of each of the plurality of upper connection wires CW’ may be in contact with the upper chip connection pad CP3 of the lower redistribution structure 100b.

For example, the plurality of upper connection wires CW’ may include copper (Cu), aluminum (Al), silver (Ag), tin (Sn), gold (Au), nickel (Ni), lead (Pb), titanium (Ti), or an alloy thereof. As an example, the plurality of upper connection wires CW’ may include gold. In some example embodiments, a constituent material of the plurality of upper connection wires CW’ may be different from a constituent material of the plurality of upper dummy wires DW’.

The plurality of upper dummy wires DW’ may include a lateral-side upper dummy wire DW’_S having a first end in contact with the lateral-side upper dummy pad DP’_S of the upper semiconductor chip 400 and a front-side upper dummy wire DW’_F having a first end in contact with the front-side upper dummy pad DP’_F of the upper semiconductor chip 400.

The first end of the lateral-side upper dummy wire DW’_S may be in contact with the lateral-side upper dummy pad DP’_S of the upper semiconductor chip 400. The lateral-side upper dummy wire DW’_S may include an exposed lateral-side upper dummy wire DW’_S1, which is exposed to the outside of the semiconductor package 1000f, and a buried lateral-side upper dummy wire DW’_S2, which is not exposed to the outside of the semiconductor package 1000f.

A first end of the exposed lateral-side upper dummy wire DW’_S1 may be in contact with the lateral-side upper dummy pad DP’_S of the upper semiconductor chip 400, and a second end of the exposed lateral-side upper dummy wire DW’_S1 may be coplanar with an outer surface of the upper molding layer ML’. A first end of the buried lateral-side upper dummy wire DW’_S2 may be in contact with the lateral-side upper dummy pad DP’_S of the upper semiconductor chip 400, and a second end of the buried lateral-side upper dummy wire DW’_S2 may be located inside the upper molding layer ML’.

In some example embodiments, the exposed lateral-side upper dummy wire DW’_S1 may include a first exposed lateral-side upper dummy wire DW’_S1a and a second exposed lateral-side upper dummy wire DW’_S1b. A second end of the first exposed lateral-side upper dummy wire DW’_S1a may be coplanar with a lateral surface of the upper molding layer ML’. A second end of the second exposed lateral-side upper dummy wire DW’_S1b may be coplanar with an upper surface of the upper molding layer ML’.

A first end of the front-side upper dummy wire DW’_F may be in contact with the front-side upper dummy pad DP’_F of the upper semiconductor chip 400. The front-side upper dummy wire DW’_F may include an exposed front-side upper dummy wire DW’_F1, which is exposed to the outside of the semiconductor package 1000f, and a buried front-side upper dummy wire DW’_F2, which is not exposed to the outside of the semiconductor package 1000f.

A first end of the exposed front-side upper dummy wire DW’_F1 may be in contact with the front-side upper dummy pad DP’_F of the upper semiconductor chip 400, and a second end of the exposed front-side upper dummy wire DW’_F1 may be coplanar with the outer surface of the upper molding layer ML’. A first end of the buried front-side upper dummy wire DW’_F2 may be in contact with the front-side upper dummy pad DP’_F of the upper semiconductor chip 400, and a second end of the buried front-side upper dummy wire DW’_F2 may be located inside the upper molding layer ML’.

In some example embodiments, the exposed front-side upper dummy wire DW’_F1 may include a first exposed front-side upper dummy wire DW’_F1a having a second end, which is coplanar with the lateral surface of the upper molding layer ML’, and a second exposed front-side upper dummy wire DW’_F1b having a second end, which is coplanar with the upper surface of the upper molding layer ML’.

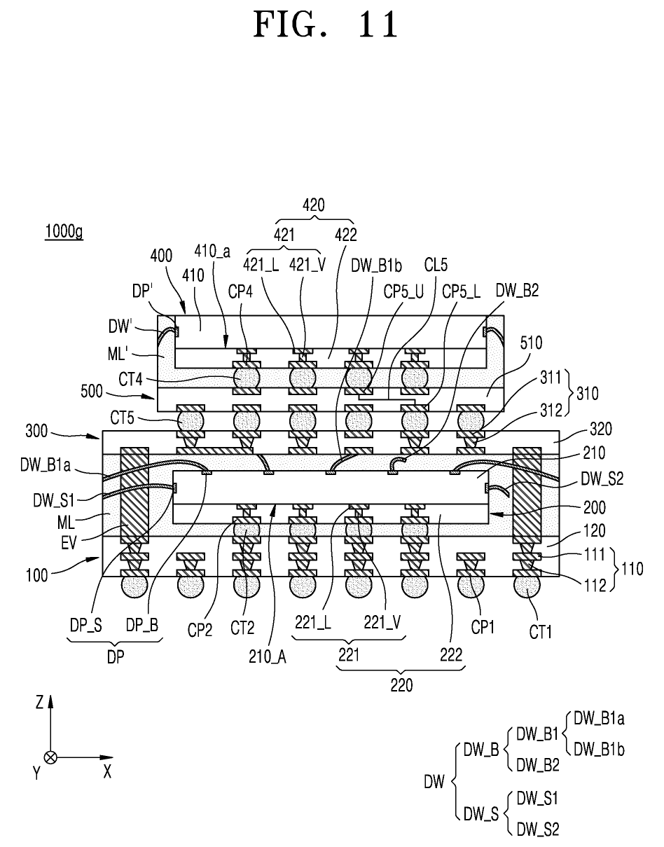

FIG. 11 is a cross-sectional view of a semiconductor package 1000g according to example embodiments.

Most of components included in the semiconductor package 1000g described below and materials forming the components are substantially the same as or similar to those described above with reference to FIG. 9. Thus, for brevity, the description below will focus on differences between the semiconductor package 1000g of FIG. 11 and the semiconductor package 1000g described above with reference to FIG. 9.

For example, the semiconductor package 1000g of FIG. 11 may pertain to an example embodiment in which a package substrate 500 on which an upper semiconductor chip 400 is mounted is mounted on the semiconductor package 1000d of FIG. 8. For instance, the semiconductor package 1000g of FIG. 11 may be a package in which the semiconductor package 1000 of FIG. 1 is mounted on the semiconductor package 1000d of FIG. 8.

Referring to FIG. 11, the semiconductor package 1000g may include a lower redistribution structure 100, a lower semiconductor chip 200, a lower molding layer ML, a plurality of lower through vias EV, a plurality of lower dummy wires DW, an upper redistribution structure 300, the package substrate 500, the upper semiconductor chip 400, an upper molding layer ML’, and a plurality of upper dummy wires DW’.

The package substrate 500 may be located on the upper redistribution structure 300. The upper semiconductor chip 400 may be mounted on the package substrate 500. For example, the package substrate 500 may electrically connect the upper semiconductor chip 400 to the upper redistribution structure 300.

The package substrate 500 may include a base insulating layer 510, upper-side connection pads CP5_U located on an upper surface of the base insulating layer 510, and lower-side connection pads CP5_L located on a lower surface of the base insulating layer 510. The upper-side connection pads CP5_U of the package substrate 500 may be electrically connected to the lower-side connection pads CP5_L of the package substrate 500 through inner wirings CL5 located inside the base insulating layer 510.

In some example embodiments, a pitch between the upper-side connection pads CP5_U may be different from a pitch between the lower-side connection pads CP5_L. For example, a pitch between the upper-side connection pads CP5_U may be less than a pitch between the lower-side connection pads CP5_L.

In some example embodiments, a size of each of the upper-side connection pads CP5_U may be different from a size of each of the lower-side connection pads CP5_L. For example, a size of each of the upper-side connection pads CP5_U may be less than a size of each of the lower-side connection pads CP5_L.

In some example embodiments, substrate connection terminals CT5 may be located between the lower-side connection pads CP5_L of the package substrate 500 and an upper redistribution pattern 310 of the upper redistribution structure 300. The package substrate 500 may be electrically connected to the upper redistribution structure 300 through the substrate connection terminals CT5.

In some example embodiments, upper connection terminals CT4 may be located between the upper-side connection pads CP5_U of the package substrate 500 and upper front-side pads CP4 of the upper semiconductor chip 400. For example, the package substrate 500 may be electrically connected to the upper semiconductor chip 400 through the upper connection terminals CT4. However, example embodiments are not limited thereto, and the package substrate 500 may be electrically connected to an upper semiconductor chip through a plurality of connection wires.

The upper semiconductor chip 400 and the plurality of upper dummy wires DW’ may substantially and respectively be the same as the upper semiconductor chip 400 and the plurality of upper dummy wires DW’ that are described above.

The upper molding layer ML’ may be located on the package substrate 500 and surround the upper semiconductor chip 400 and the plurality of upper dummy wires DW’. For example, a width of the package substrate 500 may be equal to a width of the upper molding layer ML’. A width of the package substrate 500 may be less than a width of the upper redistribution structure 300.

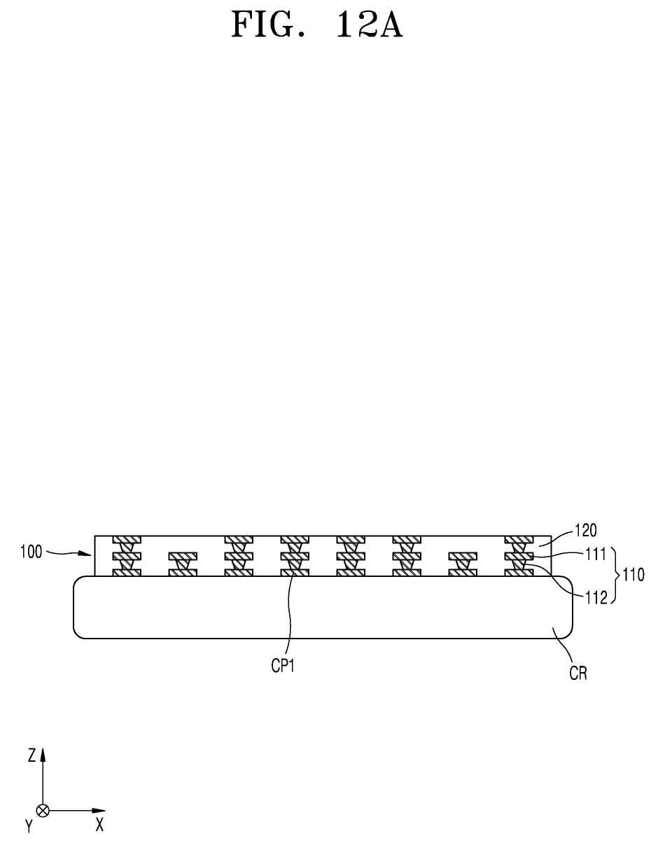

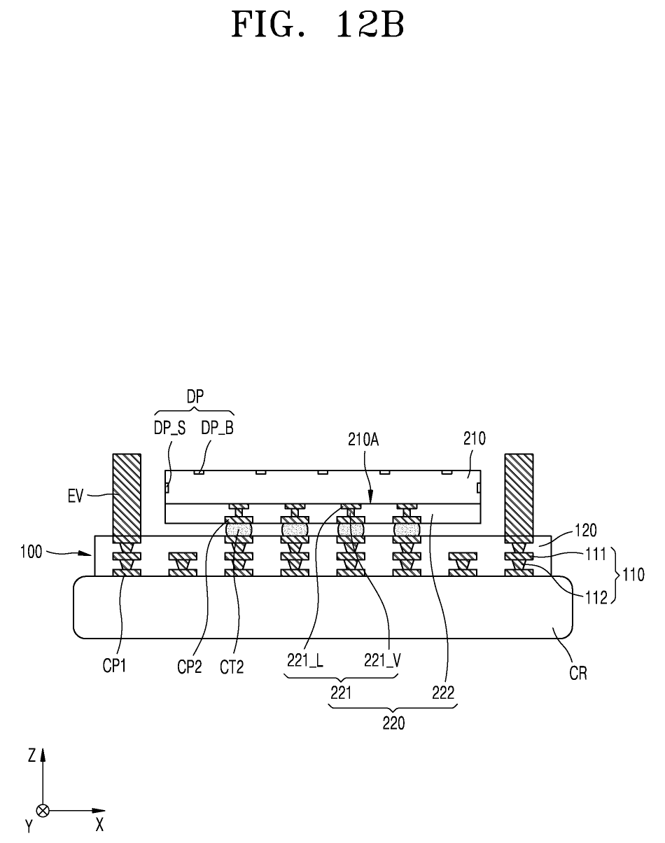

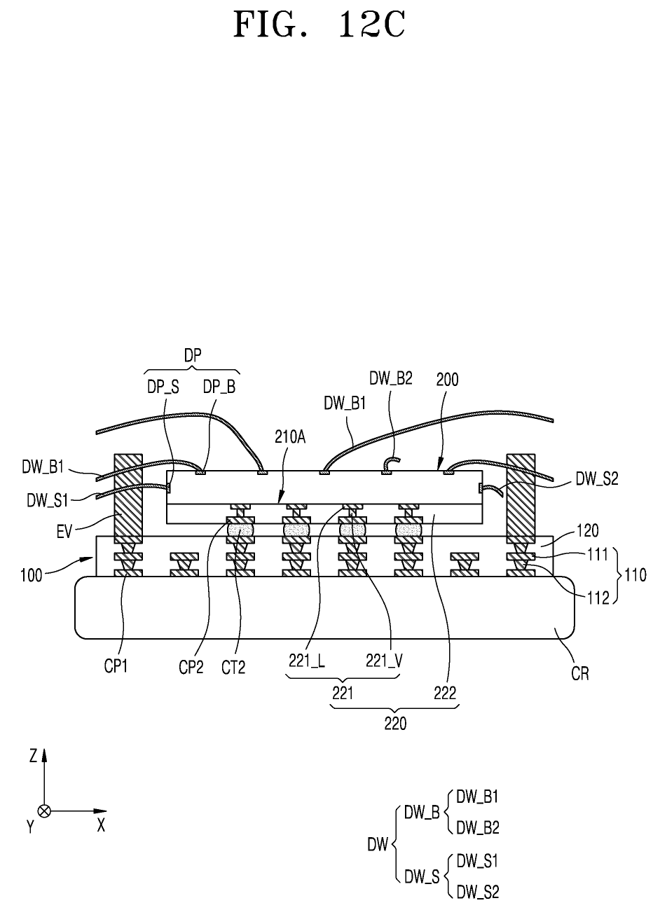

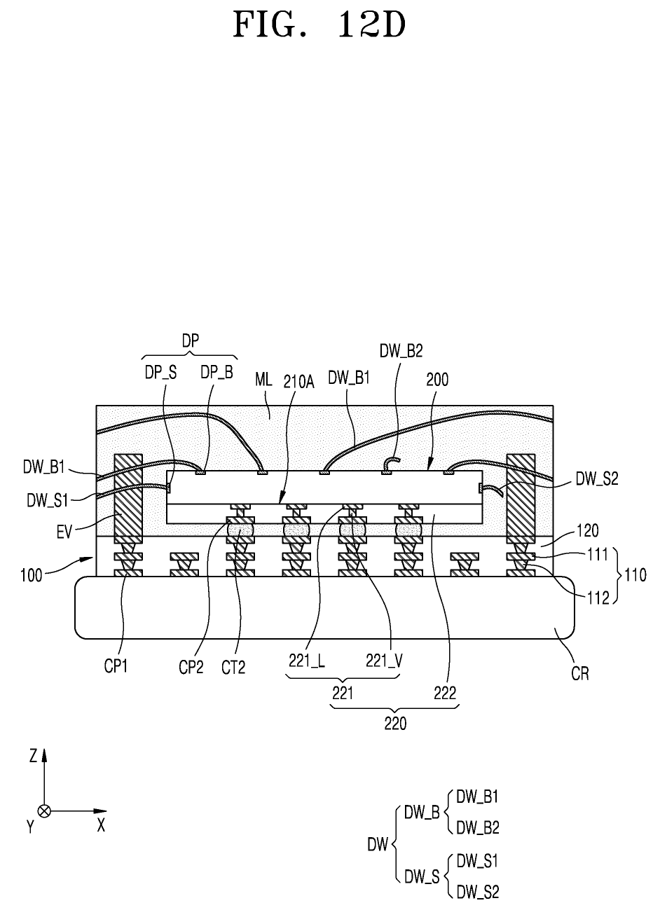

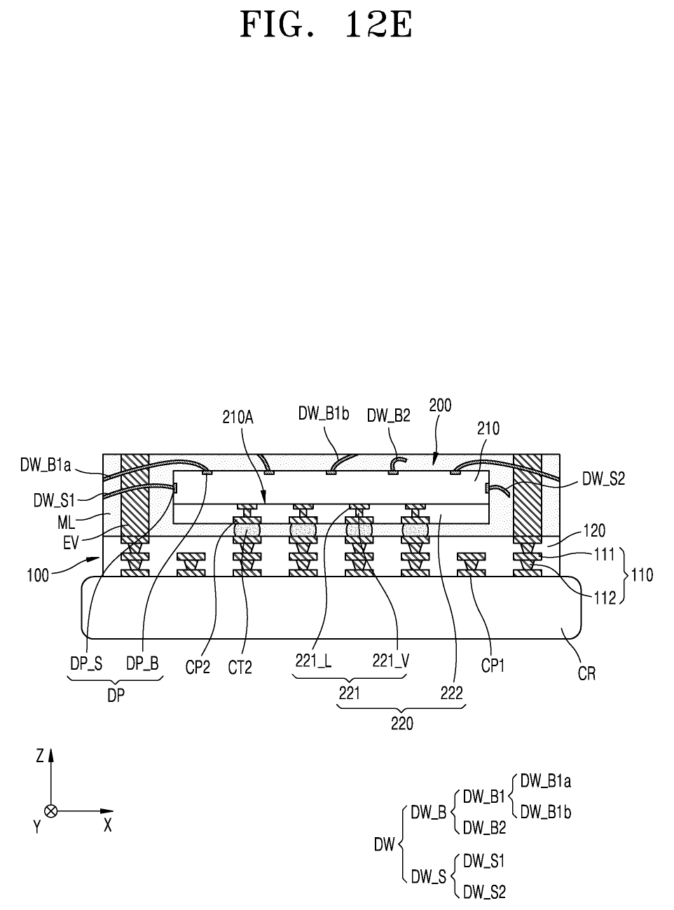

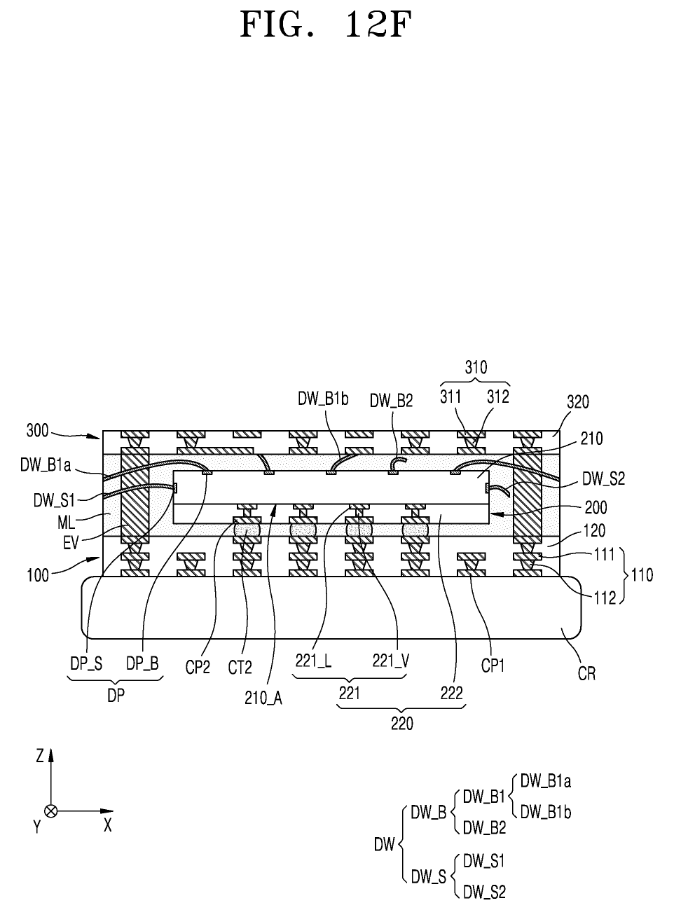

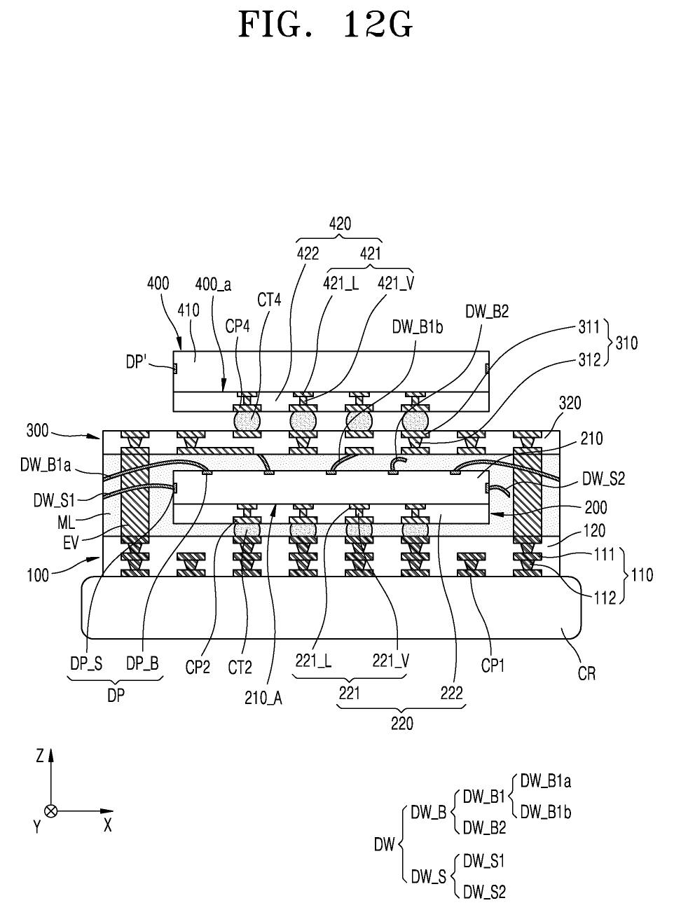

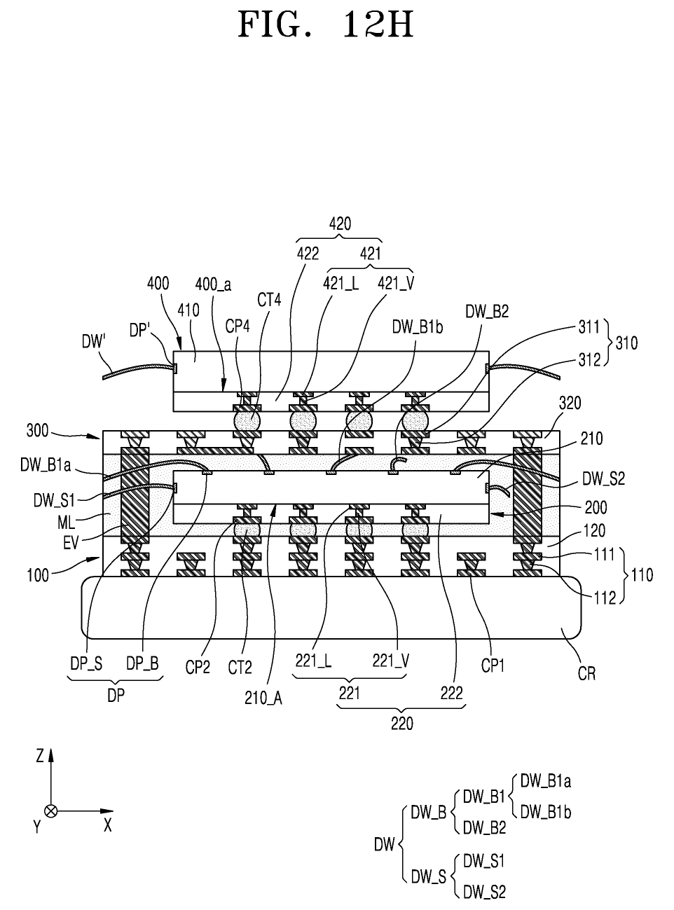

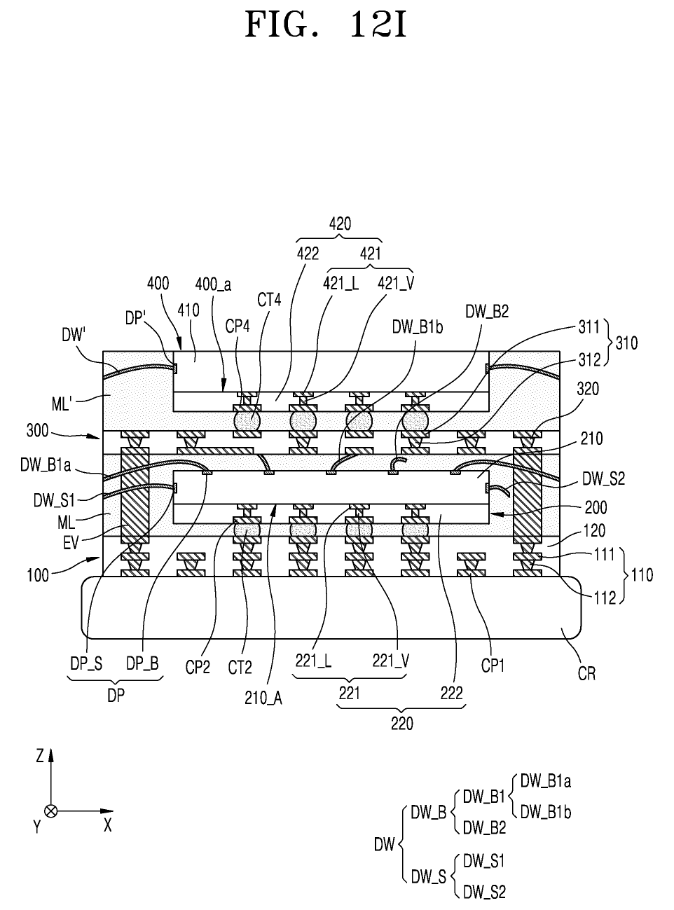

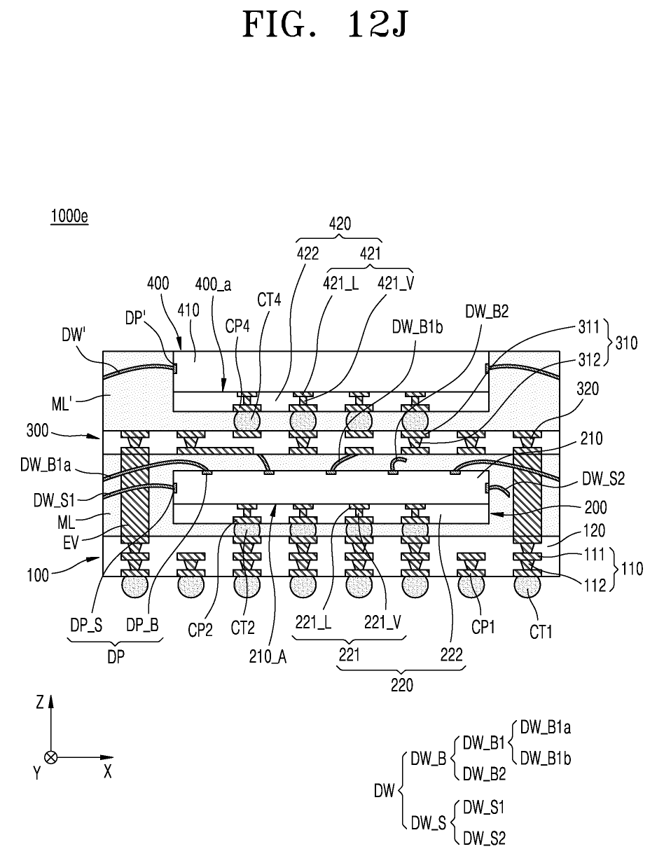

FIGS. 12A to 12J are cross-sectional views illustrating a method of manufacturing a semiconductor package 1000e, according to example embodiments. Specifically, FIGS. 12A to 23J are cross-sectional views schematically illustrating a process of manufacturing the semiconductor package 1000e of FIG. 9.

Referring to FIGS. 12A and 12B, a lower redistribution structure 100 may be formed on a carrier substrate CR, and then a lower semiconductor chip 200 and a plurality of lower through vias EV may be formed on the lower redistribution structure 100.

For example, FIGS. 12A and 12B illustrate a chip-last process in which the lower redistribution structure 100 is first formed on the carrier substrate CR, the manufacturing order of the lower redistribution structure 100 and the lower semiconductor chip 200 is not limited thereto.

For example, in FIG. 12B, the lower semiconductor chip 200 is illustrated as being mounted on the lower redistribution structure 100 by using a flip-chip method such that an active surface 210_A of a lower semiconductor substrate 210 faces the lower redistribution structure 100. However, example embodiments are not limited thereto, and the lower semiconductor chip 200 may be mounted on the lower redistribution structure 100 by using a wire-bonding method such that an inactive surface of the lower semiconductor substrate faces the lower redistribution structure 100.

In some example embodiments, the lower redistribution structure 100 may be manufactured to have a large area in which a plurality of lower semiconductor chips 200 may be mounted. For example, after the lower semiconductor chip 200 is mounted on the lower redistribution structure 100, a dicing process may be performed. However, for brevity, the description below is provided based on a state where the lower redistribution structure 100 has been diced.

The lower semiconductor chip 200 may be electrically connected to the lower redistribution structure 100, and the plurality of lower through vias EV may be electrically connected to the lower redistribution structure 100.

In some example embodiments, the lower semiconductor chip 200 may include a plurality of lower dummy pads DP. The plurality of lower dummy pads DP may be located on a lateral surface or the inactive surface of the lower semiconductor substrate 210 of the lower semiconductor chip 200. For example, the plurality of lower dummy pads DP may include a lateral-side lower dummy pad DP_S and a back-side lower dummy pad DP_B.

For example, when the lower semiconductor chip 200 is adhered to the lower redistribution structure 100 by using a wire-bonding method, the plurality of lower dummy pads DP of the lower semiconductor chip 200 may include the lateral-side lower dummy pad DP_S and a front-side lower dummy pad (refer to DP_F in FIG. 5).

Referring to FIGS. 12C and 12D, a plurality of lower dummy wires DW may be formed to be in contact with the plurality of lower dummy pads DP of the lower semiconductor chip 200. Subsequently, a lower molding layer ML may be formed on the lower redistribution structure 100 to cover the lower semiconductor chip 200 and the plurality of lower dummy wires DW.

In some example embodiments, each of the plurality of lower dummy wires DW may be formed to have a first end in contact with a corresponding one of the plurality of lower dummy pads DP and have a second end that is suspended in the air without contacting a corresponding one of the plurality of lower through vias EV, the lower semiconductor chip 200, and the lower redistribution structure 100.

In some example embodiments, each of the plurality of lower dummy wires DW may be formed to have a first end in contact with the plurality of lower dummy pads DP and have a second end in contact with a dummy pad located outside the semiconductor package 1000e, from among pads of the lower redistribution structure 100 having a large area. For example, the dummy pad located outside the semiconductor package 1000e may be a dummy pad located outside a cutting line along which the lower redistribution structure 100 will be cut.

In some example embodiments, the plurality of lower dummy wires DW may be formed not to contact the plurality of lower through vias EV. In some example embodiments, portions of the plurality of lower dummy wires DW may be at a higher vertical level than upper surfaces of the plurality of lower through vias EV.

The lower molding layer ML may completely surround the lower semiconductor chip 200 and the plurality of lower dummy wires DW. For example, the plurality of lower dummy wires DW and the lower semiconductor chip 200 may be buried inside the lower molding layer ML and may not be exposed to the outside of the lower molding layer ML.

Referring to FIG. 12E, an upper portion of the lower molding layer ML may be partially removed to expose the upper surfaces of the plurality of lower through vias EV. In some example embodiments, the lower molding layer ML may be partially removed by using a chemical mechanical polishing (CMP) process.

In some example embodiments, during the removal of the lower molding layer ML, the plurality of lower dummy wires DW may be partially removed together. For example, the plurality of lower dummy wires DW, which are partially removed during the removal of the lower molding layer ML, may be exposed back-side lower dummy wires DW_B or exposed lateral-side lower dummy wires DW_S. For example, the plurality of lower dummy wires DW, which are partially removed during the removal of the lower molding layer ML, may have a second end that is coplanar with an upper surface of the lower molding layer ML.

Referring to FIG. 12F, an upper redistribution structure 300 may be formed on the lower molding layer ML and the plurality of lower through vias EV. For example, the upper redistribution structure 300 may also be formed over a large area, like the lower redistribution structure 100. However, for brevity, the description below is provided based on a diced size of the upper redistribution structure 300.

The upper redistribution structure 300 may be electrically connected to the plurality of lower through vias EV. The upper redistribution structure 300 may be in contact with a lower dummy wire DW having a second end, which is coplanar with the upper surface of the lower molding layer ML, from among the plurality of lower dummy wires DW. For example, the lower dummy wire DW having the second end, which is coplanar with the upper surface of the lower molding layer, may be in contact with upper redistribution layers 320 of the upper redistribution structure 300.

Referring to FIG. 12G, an upper semiconductor chip 400 may be mounted on the upper redistribution structure 300. Although the upper semiconductor chip 400 is mounted on the upper redistribution structure 300 by using a flip-chip method in FIG. 12G, the upper semiconductor chip 400 may be mounted on the upper redistribution structure 300 by using a wire bonding method.

The upper semiconductor chip 400 may include a plurality of upper dummy pads DP’, which are not electrically connected to a plurality of individual devices formed on an active surface of the upper semiconductor substrate 410 of the upper semiconductor chip 400.

Referring to FIG. 12H, a plurality of upper dummy wires DW’ may be adhered to the upper semiconductor chip 400. The plurality of upper dummy wires DW’ may be formed on the plurality of upper dummy pads DP’ of the upper semiconductor chip 400. For example, a first end of each of the plurality of upper dummy wires DW’ may be in contact with a corresponding one of the plurality of upper dummy pads DP’, and a second end of each of the plurality of upper dummy wires DW’ may be suspended in the air or be in contact with a dummy pad located outside the semiconductor package 1000e, from among pads of the upper redistribution structure 300 having a large area.

Referring to FIG. 12I, an upper molding layer ML’ may be formed on the upper redistribution structure 300 to surround the upper semiconductor chip 400 and a plurality of upper dummy wires. Thereafter, an upper portion of the upper molding layer ML’ may be removed to expose an upper surface of the upper semiconductor chip 400 to the outside.

Afterwards, by performing a dicing process, the upper molding layer ML’, the upper redistribution structure 300, the lower molding layer ML, and the lower redistribution structure 100 may be cut along a cutting line. A lateral surface of the upper molding layer ML’, a lateral surface of the upper redistribution structure 300, a lateral surface of the lower molding layer ML, and a lateral surface of the lower redistribution structure 100 may be aligned with each other in a vertical direction (Z direction).

In some example embodiments, during the dicing process, portions of the plurality of lower dummy wires DW and portions of the plurality of upper dummy wires DW’ may be cut together. A second end of each of the plurality of lower dummy wires DW that are cut during the dicing process may be coplanar with the lateral surface of the lower molding layer ML. The second end of each of the plurality of upper dummy wires DW’ that are cut during the dicing process may be coplanar with the lateral surface of the upper molding layer ML’.

Referring to FIG. 12J, the carrier substrate CR may be removed from the lower redistribution structure 100, and external connection terminals CT1 may be adhered to external connection pads CP1 of the lower redistribution structure 100. The external connection terminals CT1 may include a conductive material, for example, at least one of solder, tin (Sn), silver (Ag), copper (Cu), and aluminum (Al).

In some example embodiments, the process of adhering the external connection terminals CT1 to the lower redistribution structure 100 may be performed before the lower semiconductor chip 200 is mounted on the lower redistribution structure 100.

While the inventive concept has been particularly shown and described with reference to embodiments thereof, it will be understood that various changes in form and details may be made therein without departing from the spirit and scope of the following claims.

What is claimed is:

1. A semiconductor package comprising:
a redistribution structure;
a semiconductor chip on the redistribution structure, the semiconductor chip comprising a semiconductor substrate, a wiring structure, and a plurality of dummy pads, the semiconductor substrate comprising an active surface and an inactive surface opposite to the active surface, and the wiring structure being on the active surface of the semiconductor substrate; and
a plurality of dummy wires each having a first end in contact with a corresponding one of the plurality of dummy pads of the semiconductor chip and a second end opposite to the first end, the second end being spaced apart from the semiconductor chip and the redistribution structure,
wherein the plurality of dummy pads of the semiconductor chip comprise a lateral-side dummy pad on a lateral surface of the semiconductor substrate, and
wherein the plurality of dummy wires comprise a lateral-side dummy wire, the first end of the lateral-side dummy wire being in contact with the lateral-side dummy pad of the semiconductor chip.

2. The semiconductor package of claim 1, further comprising a molding layer on the redistribution structure, the molding layer being in contact with the lateral surface of the semiconductor chip and an outer surface of each of the plurality of dummy wires,
wherein an upper surface of the molding layer is coplanar with an upper surface of the semiconductor chip.

3. The semiconductor package of claim 2, wherein the lateral-side dummy wire comprises an exposed lateral-side dummy wire, the second end of the exposed lateral-side dummy wire being coplanar with an outer surface of the molding layer.

4. The semiconductor package of claim 2, wherein the lateral-side dummy wire comprises a buried lateral-side dummy wire, the second end of the buried lateral-side dummy wire being located inside the molding layer.

5. The semiconductor package of claim 1, wherein the semiconductor chip is located on the redistribution structure such that the inactive surface of the semiconductor substrate faces the redistribution structure,
wherein the wiring structure of the semiconductor chip comprises a front-side pad electrically connected to a plurality of individual devices on the active surface of the semiconductor substrate, and
wherein the semiconductor package further comprises a plurality of connection wires each having a first end in contact with the front-side pad of the wiring structure of the semiconductor chip and a second end opposite to the first end, the second end of each of the plurality of connection wires being in contact with the redistribution structure.

6. The semiconductor package of claim 5, wherein the plurality of dummy pads of the semiconductor chip further comprise a front-side dummy pad located on the wiring structure, and
wherein the plurality of dummy wires further comprise a front-side dummy wire, the first end of the front-side dummy wire being in contact with the front-side dummy pad of the semiconductor chip.

7. The semiconductor package of claim 1, wherein the semiconductor chip is located on the redistribution structure such that the active surface of the semiconductor substrate faces the redistribution structure,
wherein the plurality of dummy pads of the semiconductor chip further comprise a back-side dummy pad located on the inactive surface of the semiconductor substrate, and
wherein the plurality of dummy wires further comprise a back-side dummy wire, the first end of the back-side dummy wire being in contact with the back-side dummy pad of the semiconductor chip.

8. The semiconductor package of claim 7, further comprising a molding layer on the redistribution structure, the molding layer being in contact with a lateral surface of the semiconductor chip and the plurality of dummy wires,
wherein the molding layer covers an upper surface of the semiconductor chip.

9. The semiconductor package of claim 1, wherein the semiconductor chip further comprises a plurality of individual devices on the active surface of the semiconductor substrate, the plurality of individual devices being electrically connected to the wiring structure, and
wherein the plurality of dummy pads of the semiconductor chip are electrically insulated from the plurality of individual devices located on the active surface of the semiconductor substrate of the semiconductor chip.

10. A semiconductor package comprising:
a lower redistribution structure;
a lower semiconductor chip on the lower redistribution structure, the lower semiconductor chip comprising a lower semiconductor substrate, a lower wiring structure, and a plurality of lower dummy pads, the lower semiconductor substrate comprising an active surface and an inactive surface opposite to the active surface, and the lower wiring structure being on the active surface of the lower semiconductor substrate;
a plurality of lower dummy wires each having a first end in contact with a corresponding one of the plurality of lower dummy pads of the lower semiconductor chip and a second end opposite to the first end, the second end of each of the plurality of lower dummy wires being spaced apart from the lower redistribution structure and the lower semiconductor chip;
a lower molding layer on the lower redistribution structure, the lower molding layer being in contact with the lower semiconductor chip and the plurality of lower dummy wires;
a plurality of lower through vias on the lower redistribution structure, the plurality of lower through vias extending from a lower surface of the lower molding layer to an upper surface of the lower molding layer; and
an upper redistribution structure on the lower molding layer, the upper redistribution structure being electrically connected to the plurality of lower through vias.

11. The semiconductor package of claim 10, wherein the plurality of lower dummy pads of the lower semiconductor chip comprise a lateral-side lower dummy pad on a lateral surface of the lower semiconductor substrate and a back-side lower dummy pad on the inactive surface of the lower semiconductor substrate, and
wherein the plurality of lower dummy wires comprise a lateral-side lower dummy wire and a back-side lower dummy wire, wherein the first end of the lateral-side lower dummy wire is in contact with the lateral-side lower dummy pad of the lower semiconductor chip, and the first end of the back-side lower dummy wire is in contact with the back-side lower dummy pad of the lower semiconductor chip.

12. The semiconductor package of claim 11, wherein the lateral-side lower dummy wire comprises a first exposed lateral-side lower dummy wire, a second exposed lateral-side lower dummy wire and a buried lateral-side lower dummy wire, wherein the second end of the first exposed lateral-side lower dummy wire is coplanar with a lateral surface of the lower molding layer, the second end of the second exposed lateral-side lower dummy wire is in contact with the upper redistribution structure, and the second end of the buried lateral-side lower dummy wire is inside the lower molding layer.

13. The semiconductor package of claim 11, wherein the back-side lower dummy wire comprises a first exposed back-side lower dummy wire, a second exposed back-side lower dummy wire and a buried back-side lower dummy wire, wherein the second end of the first exposed back-side lower dummy wire is coplanar with a lateral surface of the lower molding layer, the second end of the second exposed back-side lower dummy wire is in contact with the upper redistribution structure, and the second end of the buried back-side lower dummy wire is inside the lower molding layer .

14. The semiconductor package of claim 10, wherein the plurality of lower dummy wires are spaced apart from the plurality of lower through vias.

15. The semiconductor package of claim 10, wherein a lateral surface of the lower redistribution structure, a lateral surface of the lower molding layer, and a lateral surface of the upper redistribution structure are coplanar with each other.

16. A semiconductor package comprising:
a lower redistribution structure;
a lower semiconductor chip on the lower redistribution structure, the lower semiconductor chip comprising a lower semiconductor substrate, a lower wiring structure, and a plurality of lower dummy pads, the lower semiconductor substrate comprising an active surface and an inactive surface opposite to the active surface, and the lower wiring structure being on the active surface of the lower semiconductor substrate;
a plurality of lower dummy wires each having a first end in contact with a corresponding one of the plurality of lower dummy pads of the lower semiconductor chip and a second end opposite to the first end, the second end of each of the plurality of lower dummy wires being spaced apart from the lower redistribution structure and the lower semiconductor chip;
a lower molding layer on the lower redistribution structure, the lower molding layer being in contact with the lower semiconductor chip and the plurality of lower dummy wires;
a plurality of lower through vias located on the lower redistribution structure and extending from a lower surface of the lower molding layer to an upper surface thereof;
an upper redistribution structure on the lower molding layer, the upper redistribution structure being electrically connected to the plurality of lower through vias;
an upper semiconductor chip on the upper redistribution structure, the upper semiconductor chip comprising an upper semiconductor substrate, an upper wiring structure, and a plurality of upper dummy pads, the upper semiconductor substrate comprising an active surface and an inactive surface opposite to the active surface, and the upper wiring structure on the active surface of the upper semiconductor substrate; and
a plurality of upper dummy wires each having a first end in contact with a corresponding one of the plurality of upper dummy pads and a second end opposite to the first end, the second end of each of the plurality of upper dummy wires being spaced apart from the upper redistribution structure and the upper semiconductor chip.

17. The semiconductor package of claim 16, wherein the plurality of upper dummy pads of the upper semiconductor chip comprise a lateral-side upper dummy pad on a lateral surface of the upper semiconductor substrate of the upper semiconductor chip, and
wherein the plurality of upper dummy wires comprise a lateral-side upper dummy wire, the first end of the lateral-side upper dummy wire being in contact with the lateral-side upper dummy pad of the upper semiconductor chip.

18. The semiconductor package of claim 17, further comprising an upper molding layer on the upper redistribution structure, the upper molding layer surrounding the upper semiconductor chip and the plurality of upper dummy wires,
wherein an upper surface of the upper molding layer is coplanar with an upper surface of the upper semiconductor chip.

19. The semiconductor package of claim 16, wherein the upper semiconductor chip is on the upper redistribution structure such that the inactive surface of the upper semiconductor substrate faces the upper redistribution structure,
wherein the upper wiring structure of the upper semiconductor chip comprises a front-side pad electrically connected to a plurality of individual devices provided on the active surface of the upper semiconductor substrate, and
wherein the semiconductor package further comprises a plurality of upper connection wires electrically connected to the front-side pad of the upper wiring structure of the upper semiconductor chip and the upper redistribution structure.

20. The semiconductor package of claim 19, wherein the plurality of upper dummy pads of the upper semiconductor chip further comprise a front-side upper dummy pad on the upper wiring structure, and
wherein the plurality of upper dummy wires comprise a front-side upper dummy wire, the first end of the front-side upper dummy wire being in contact with the front-side upper dummy pad of the upper semiconductor chip.
